(19) United States
(12) Patent Application Publication
(10) Pub. No.: US 2024/0222430 A1
(43) Pub. Date: Jul. 4, 2024

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Huang-Chao CHANG, Hsinchu City (TW); Ta-Chun LIN, Hsinchu (TW); Chun-Sheng LIANG, Changhua County (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/149,215

(22) Filed: Jan. 3, 2023

(51) Int. Cl. H01L 29/06; H01L 21/8234; H01L 29/417; H01L 29/423; H01L 29/66; H01L 29/786

(52) U.S. Cl. CPC H01L 29/0673; H01L 21/823412; H01L 21/823418; H01L 29/41733; H01L 29/42392; H01L 29/66545; H01L 29/78696

(57) ABSTRACT

A semiconductor device includes a dielectric wall, an isolation structure, first and second semiconductor channels, and a gate structure. The dielectric wall is on a substrate and extending along a first direction from a top view. The isolation structure is in the substrate and having a top surface lower than that of the dielectric wall. The first and second semiconductor channels are respectively on opposite first and second sides of the dielectric wall. The gate structure extends across the first and second semiconductor channels along a second direction different from the first direction from the top view. From the top view the gate structure comprises a first profile over the first semiconductor channels and a second profile over the isolation structure, the first profile has a first width at the first side of the dielectric wall, and the first width is greater than a width of the second profile.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12D illustrate schematic views of intermediate stages in the manufacture of a semiconductor device in accordance with some embodiments of the present disclosure.

FIGS. 13A-13C illustrate schematic views of a semiconductor device in accordance with some embodiments of the present disclosure.

FIGS. 14A-14B illustrate schematic views of a semiconductor device in accordance with some embodiments of the present disclosure.

FIGS. 15A and 15B illustrate top views of intermediate stages in the manufacture of a semiconductor device in accordance with some embodiments of the present disclosure.

FIGS. 16A and 16B illustrate top views of intermediate stages in the manufacture of a semiconductor device in accordance with some embodiments of the present disclosure.

FIGS. 17A and 17B illustrate top views of intermediate stages in the manufacture of a semiconductor device in accordance with some embodiments of the present disclosure.

FIGS. 18A and 18B illustrate top views of intermediate stages in the manufacture of a semiconductor device in accordance with some embodiments of the present disclosure.

FIGS. 19A and 19B illustrate top views of intermediate stages in the manufacture of a semiconductor device in accordance with some embodiments of the present disclosure.

FIGS. 20A and 20B illustrate top views of intermediate stages in the manufacture of a semiconductor device in accordance with some embodiments of the present disclosure.

FIGS. 21A and 21B illustrate top views of intermediate stages in the manufacture of a semiconductor device in accordance with some embodiments of the present disclosure.

FIGS. 22A and 22B illustrate top views of intermediate stages in the manufacture of a semiconductor device in accordance with some embodiments of the present disclosure.

FIGS. 23A and 23B illustrate top views of intermediate stages in the manufacture of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

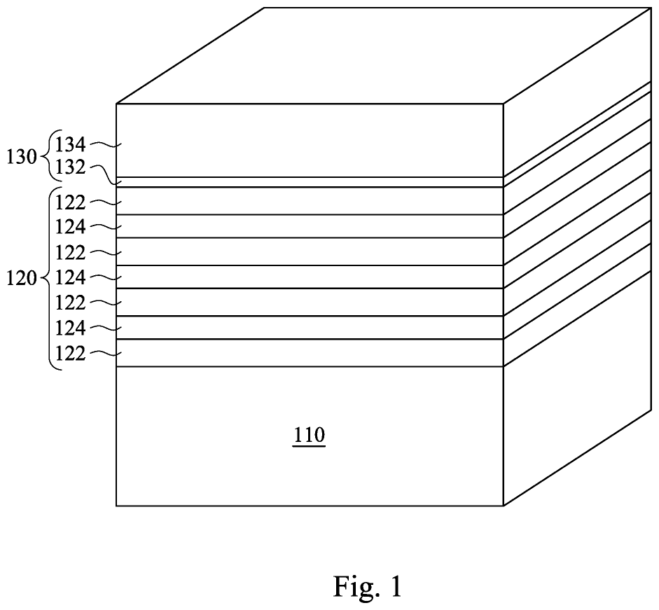

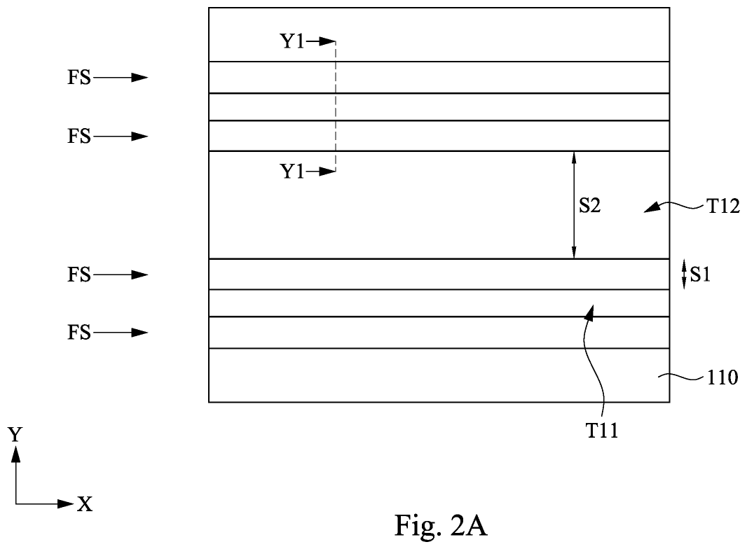

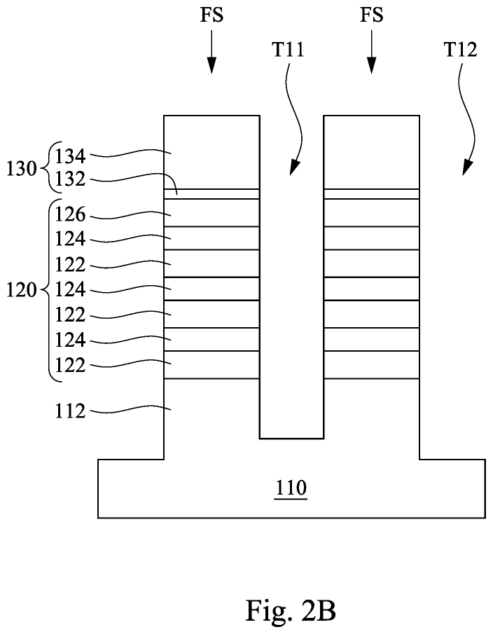

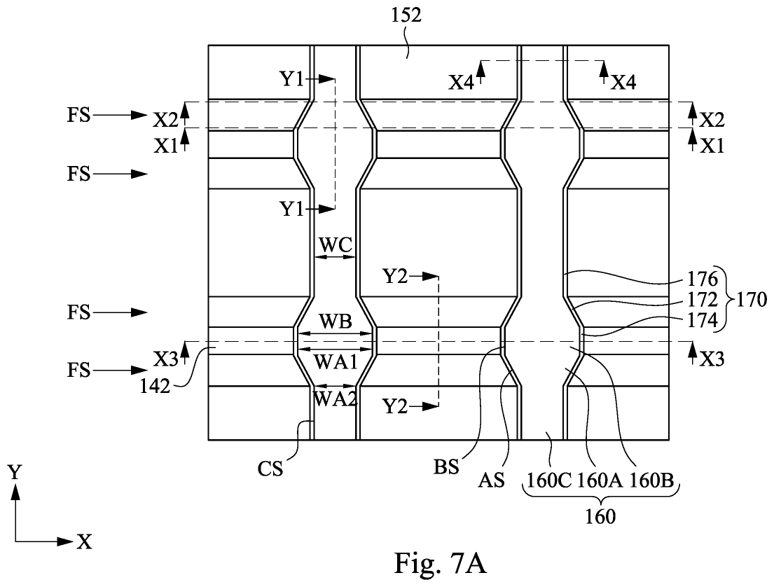

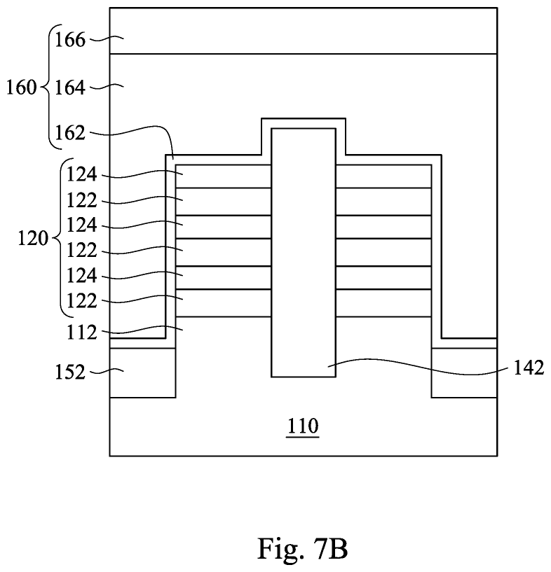

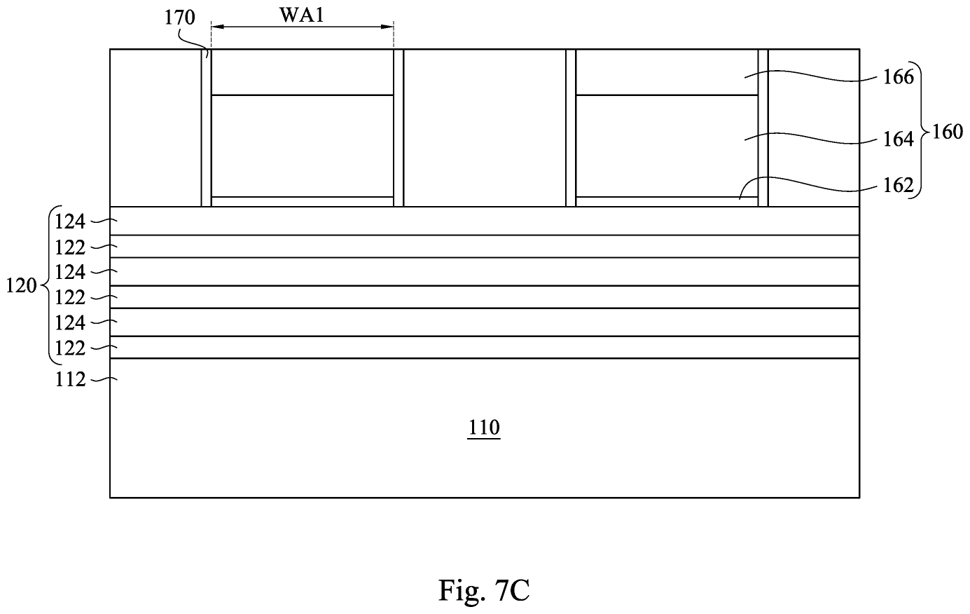

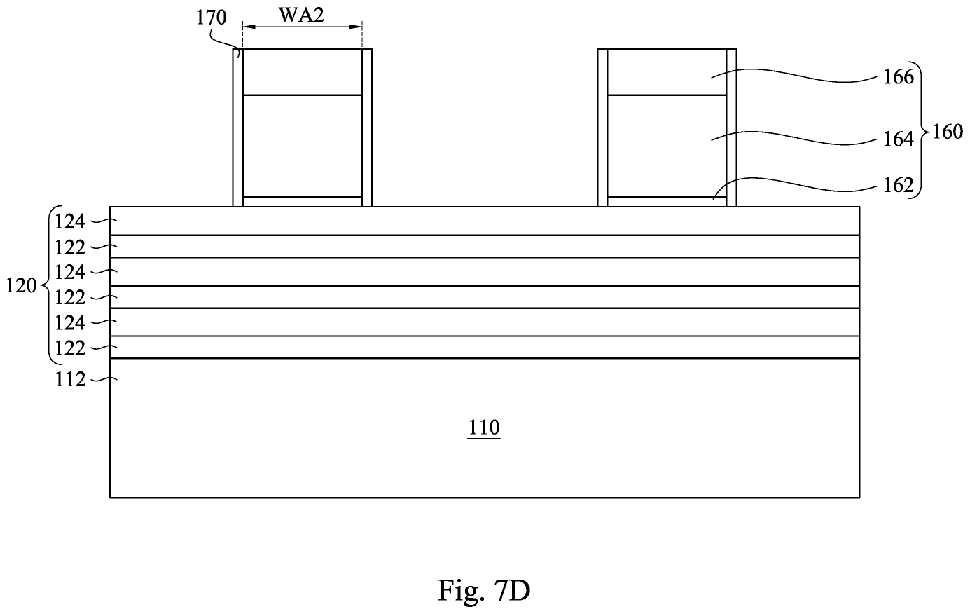

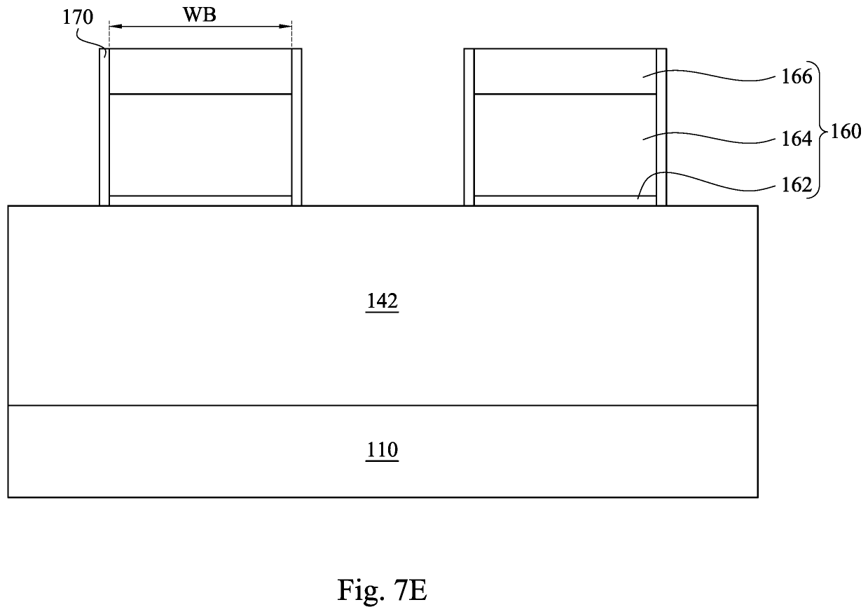

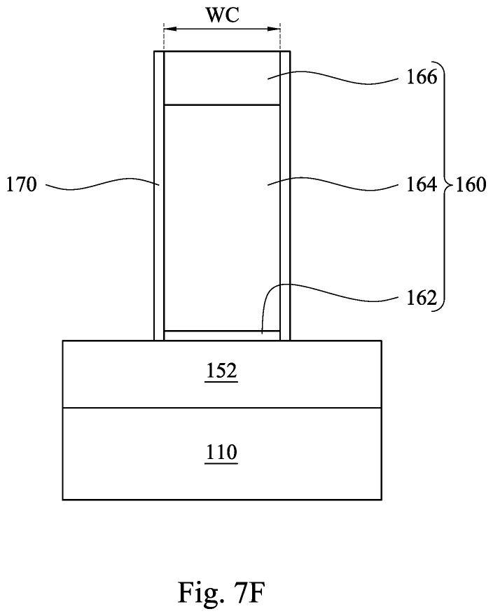

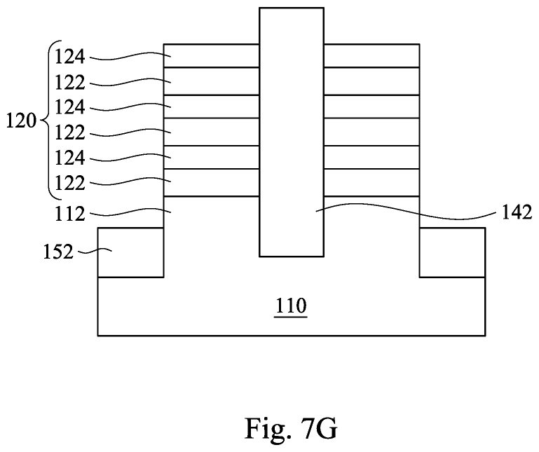

FIGS. 1-12D illustrate schematic views of intermediate stages in the manufacture of a semiconductor device in accordance with some embodiments of the present disclosure. FIG. 1 is a schematic view of the semiconductor device at various stages in accordance with some embodiments. FIGS. 2A, 4A, 5A, 7A, 8A, 9A, 10A, 11A, and 12A are top views of the semiconductor device at various stages in accordance with some embodiments. FIGS. 2B, 3, 4B, 5B, 6, 7B, 10B, 11B, and 12B are cross-sectional views of the semiconductor device (e.g., taken along line Y1-Y1 in FIGS. 2A, 4A, 5A, 7A, 10A, 11A, 12A) at various manufacturing stages in accordance with some embodiments. FIGS. 7C, 8B, 9B, 10C, 11C, and 12C are cross-sectional views of the semiconductor device (e.g., taken along line X1-X1 in FIGS. 2A, 7A, 8A, 9A, 10A, 11A, and 12A) at various manufacturing stages in accordance with some embodiments. FIGS. 7D, 8C, 9C. 10D, and 11D are cross-sectional views of the semiconductor device (e.g., taken along line X2-X2 in FIGS. 7A, 8A, 9A, 10A, and 11A) at various manufacturing stages in accordance with some embodiments. FIGS. 7E, 8D, 9D, 10E, and 11E are cross-sectional views of the semiconductor device (e.g., taken along line X3-X3 in FIGS. 7A, 8A, 9A, 10A, and 11A) at various manufacturing stages in accordance with some embodiments. FIGS. 7F, 10F, and 11F are cross-sectional views of the semiconductor device (e.g., taken along line X4-X4 in FIGS. 7A, 10A, and 11A) at various manufacturing stages in accordance with some embodiments. FIGS. 7G, 8E, 9E, and 12D are cross-sectional views of the semiconductor device (e.g., taken along line Y2-Y2 in FIGS. 7A, 8A, 9A, and 12A) at various manufacturing stages in accordance with some embodiments. It is understood that additional steps may be provided before, during, and after the steps shown in FIGS. 1-12D, and some of the steps described below can be replaced or eliminated for additional embodiments of the method. The order of the operations/processes may be interchangeable.

Reference is made to FIG. 1. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes sacrificial layers 122 interposed by channel layers 124. The sacrificial layers 122 and the channel layers 124 may have different semiconductor compositions from each other. In some embodiments, the sacrificial layers 122 and the channel layers 124 may include SiGe with different semiconductor compositions. For example, for forming an n-type device, a Si concentration in the sacrificial layers 122 is less than a Si concentration in the channel layers 124. Stated differently, in the embodiments, for forming an n-type device, a Ge concentration in the sacrificial layers 122 is greater than a Ge concentration in the channel layers 124. For example, the sacrificial layers 122 are SiₓGe₁₋ₓ, and the channel layers 124 are Si_{y}Ge_{1-y}, in which x, y, z are in a range from 0 to 1, and y>x. However, other embodiments are possible including those that provide for the material/compositions having different oxidation rates and/or etch selectivity. In some embodiments where the sacrificial layers 122 include SiGe and the channel layers 124 include Si, the Si oxidation rate of the channel layers 124 is less than the SiGe oxidation rate of the middle epitaxial layers 122m.

The channel layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 124 may be referred to as semiconductor channels in the context. The use of the channel layers 124 to define a channel or channels of a device is further discussed below.

In the present embodiments, three layers of the sacrificial layers 122 and three layers of the channel layers 124 are alternately arranged as illustrated in FIG. 1. It can be appreciated that any number of epitaxial layers can be formed in the epitaxial stack 120; the number of layers depending on the desired number of channels regions for the transistor. In some embodiments, the number of channel layers 124 is between 2 and 10. The sacrificial layers 122 in channel regions(s) may eventually be removed and serve to define a vertical distance between adjacent channel region(s) for a subsequently-formed multi-gate device. The sacrificial layer 122 may have a thickness greater than that of the channel layers 124. In some other embodiments, the sacrificial layer 122 may have a thickness equal to or less than that of the channel layers 124.

The epitaxial stack 120 may also include a topmost sacrificial layer 126 over the sacrificial layers 122 and the channel layers 124. The topmost sacrificial layer 126 have a different semiconductor composition from the channel layers 124. For example, the topmost sacrificial layer 126 may have a same semiconductor composition as that of the sacrificial layers 122.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the channel layers 124 include suitable semiconductor material, such as like Si, Ge, Sn, SiGe, GeSn, III-V semiconductor, the like, or the combination thereof. In some embodiments, the channel layers 124 may include a same semiconductor material as that substrate 110. In some embodiments, the epitaxially grown sacrificial layers 122 and 126 include a different material than the substrate 110. For example, the sacrificial layers 122 and 126 include suitable semiconductor material, such as Si, Ge, SiGe, GeSn, III-V semiconductor, the like, or the combination thereof. In some other embodiments, at least one of the layers 122, 124, and 126 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the layers 122, 124, and 126 may be chosen based on providing differing oxidation and/or etching selectivity properties. In some embodiments, the layers 122, 124, and 126 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 2A and 2B. A plurality of semiconductor fins FS extending from the substrate 110 are formed. The semiconductor fins FS may extend substantially along a direction X. In various embodiments, each of the fins FS includes a substrate portion 112 formed from the substrate 110 and portions of each of the epitaxial layers of the epitaxial stack 120 including epitaxial layers 122, 124, and 126. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

In the embodiments as illustrated in FIGS. 1 and 2B, a hard mask (HM) layer 130 is formed over the epitaxial stack 120 prior to patterning the fins FS. In some embodiments, the HM layer 130 includes an oxide layer 132 (e.g., a pad oxide layer that may include SiO₂) and a nitride layer 134 (e.g., a pad nitride layer that may include Si₃N₄) formed over the oxide layer. The oxide layer 132 may act as an adhesion layer between the epitaxial stack 120 and the nitride layer 134 and may act as an etch stop layer for etching the nitride layer 134. In some examples, the HM oxide layer 132 includes thermally grown oxide, chemical vapor deposition (CVD)-deposited oxide, and/or atomic layer deposition (ALD)-deposited oxide. In some embodiments, the HM nitride layer 134 is deposited on the HM oxide layer 132 by CVD and/or other suitable techniques.

The fins FS may subsequently be fabricated using suitable processes including photolithography and etch processes. The photolithography process may include forming a photoresist layer (not shown) over the HM layer 130, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches T11 and T12 in unprotected regions through the HM layer 130, through the epitaxial stack 120, and into the substrate 110, thereby leaving the plurality of extending fins FS. The trenches T11 and T12 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

In some embodiments, the formed fins FS may be paired. Each pair of the fins FS may have a first spacing S1 therebetween, and two neighboring pairs of the fins FS may have a second spacing therebetween, in which the second spacing S2 is greater than the first spacing S1. For example, each of the trenches T11 is located between a pair of fins FS, and the trenches T12 is located between two neighboring pairs of the fins FS, in which the trenches T11 is narrower than the trenches T12.

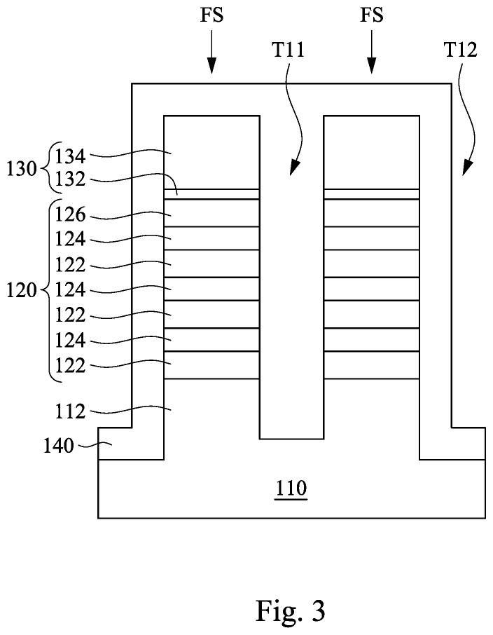

Reference is made to FIG. 3. A dielectric layer 140 is formed in sequence on the fins FS and the HM layer 130. For example, the dielectric layer 140 is conformally deposited on the structure in FIG. 2B using CVD, ALD, or a suitable method. The dielectric layer 140 lines sidewalls and bottom surface of the trenches T1. The dielectric layer 140 may include low-k dielectric materials. The dielectric layer 140 may be a single-layer or a multi-layer structure. In some embodiments, the dielectric layer 140 includes SiN, SiCN, SiOC, SiOCN or the like. Due to various spacing S1 and S2 between the fins FS, the dielectric layer 140 completely fills the trench T11, which is narrower than the trench T12, but does not completely fill the trench T12.

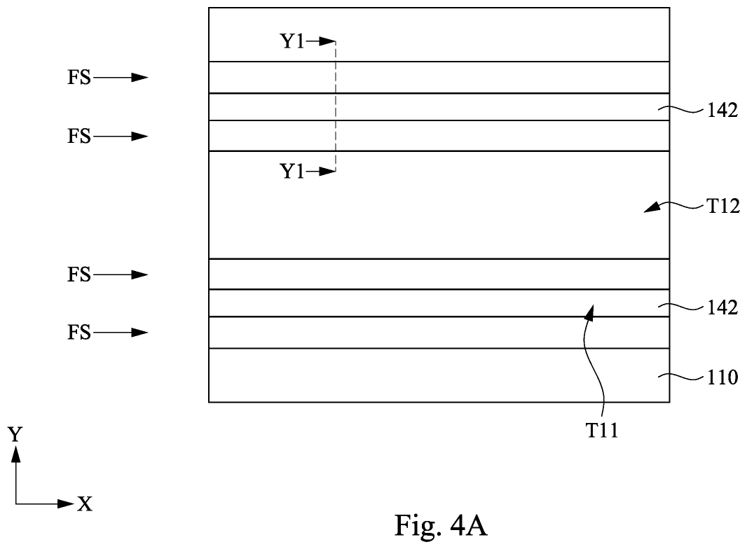

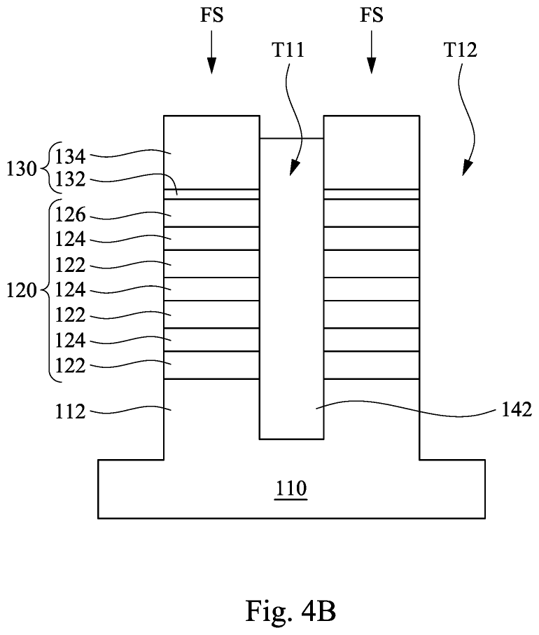

Reference is made to FIGS. 4A and 4B. An etching back process is performed to remove a top portion of the dielectric layer 140 (referring to FIG. 3) in the trenches T11 and completely remove the dielectric layer 140 from the trenches T12. In some embodiments, the etching back process may be a dry etching process that uses oxygen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Unlike the narrower trenches T11 which are entirely filled by the dielectric layer 140 (referring to FIG. 3), the wider trenches T12 allow etchant to etch sidewalls and bottom surface of the dielectric layer 140 (referring to FIG. 3) from inside the trenches T12, such that the dielectric layer 140 (referring to FIG. 3) are removed from the wider trenches T12 in a faster rate than from the narrower trenches T11. As shown in FIGS. 4A and 4B, the dielectric layer 140 (referring to FIG. 3) are removed from the wider trenches T12, while a portion of the dielectric layer 140 (referring to FIG. 3) remains in the narrower trenches T11. The remaining portion of the dielectric layer 140 may be referred to as dielectric walls 142 hereinafter. In the context, the dielectric walls 142 may be referred to dielectric fins. The etching back process, a top end of the dielectric walls 142 may be higher than a top surface of the epitaxial stack 120 and lower than a top surface of the HM layer 130.

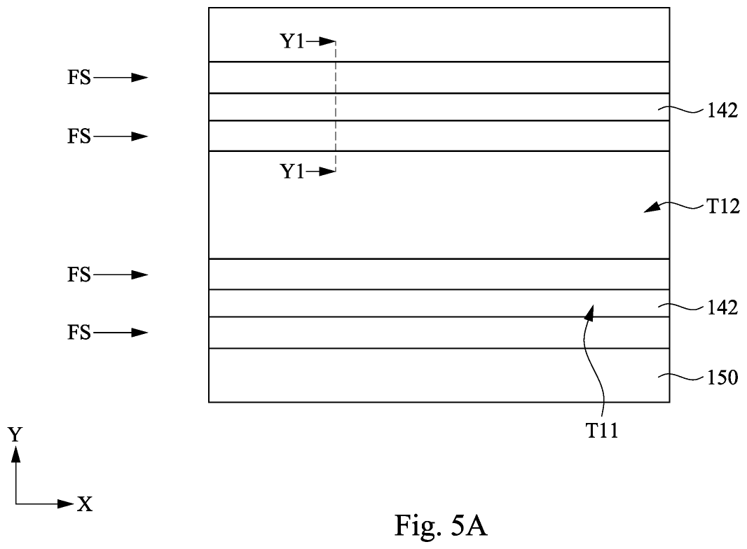

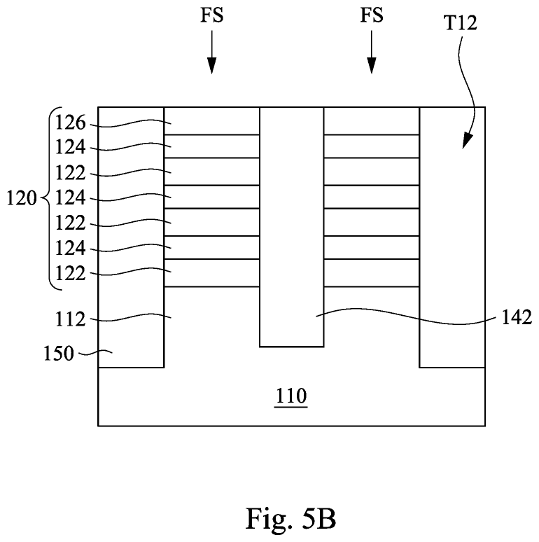

Reference is made to FIGS. 5A and 5B. A dielectric material 150 is formed over the substrate 100 and on opposing sides of the fins FS. The dielectric material 150 may include silicon oxide, silicon nitride, silicon oxynitride, fluorine-doped silicate glass (FSG), a low-k dielectric, combinations thereof, and/or other suitable materials. In various examples, the dielectric material 150 may be deposited by a CVD process, a subatmospheric CVD (SACVD) process, a flowable CVD process, an ALD process, a physical vapor deposition (PVD) process, and/or other suitable process. In some embodiments, the dielectric material 150 may include a multi-layer structure, for example, having one or more liner layers. Other dielectric materials formed by any acceptable process may be used. In the illustrated embodiments, the dielectric material 150 is silicon oxide formed by a FCVD process. An anneal process may be performed after the dielectric material 150 is formed. The dielectric material 150 may have materials different from the materials of the dielectric walls 142 to achieve etching selectivity.

In some embodiments, the dielectric material 150 is formed to overfill the trenches T12, such that excess dielectric material 150 covers the fins FS. Next, a removal process is applied to the dielectric material 150 to remove excess dielectric material 150 over the fins FS. The HM layers 130 (referring to FIG. 4B) are removed by the removal process. In some embodiments, a planarization process such as a chemical mechanical polish (CMP), an etch back process, combinations thereof, or the like may be utilized. The planarization process exposes the epitaxial stack 120 (e.g., the topmost sacrificial layer 126) such that top surfaces of the epitaxial stack 120 (e.g., the topmost sacrificial layer 126) and the dielectric wall 142 are level after the planarization process is complete.

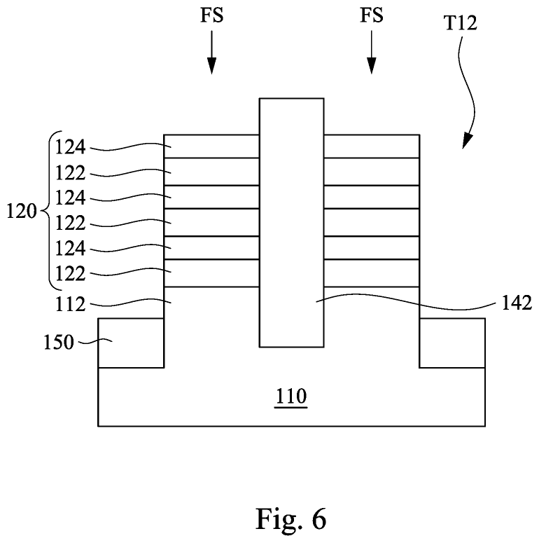

Reference is made to FIG. 6. An etching back process is performed to remove a top portion of the dielectric material 150 (referring to FIGS. 5A and 5B) above the substrate portion 112, thereby recessing the dielectric material 150 (referring to FIGS. 5A and 5B). In some embodiments, a recessing depth is controlled (e.g., by controlling an etching time) so as to result in a desired height of the exposed upper portion of the fins FS. In the illustrated embodiments, the desired height exposes each of the layers 122 and 124 of the epitaxial stack 120 in the fins FS. Due to the etch selectivity between the channel layer 124 and the dielectric material 150 (referring to FIGS. 5A and 5B), the etching back process may not substantially damage the topmost channel layer 124. After the etching back process, portions of the dielectric material 150 (referring to FIGS. 5A and 5B) remain in the trenches T12 and interpose the fins FS. The remaining portions of the dielectric material 150 (referring to FIGS. 5A and 5B) may be referred to as shallow trench isolation (STI) structures 152.

Prior to, during, or after recessing the dielectric material 150 (referring to FIGS. 5A and 5B), one or more etch processes may remove the topmost sacrificial layer 126, thereby exposing a topmost channel layer 124. In some embodiments in which the topmost sacrificial layer 126 includes SiGe, and the channel layer 124 include Si or SiC, a dry etch process with tetramethylammonium hydroxide (TMAH), ammonium hydroxide (NH4OH), or the like may be used to remove the topmost sacrificial layer 126. Due to the etch selectivity between the topmost sacrificial layer 126 and the channel layer 124, the etching process selectively removes the topmost sacrificial layer 126 without substantially damaging the topmost channel layer 124.

Reference is made to FIGS. 7A-7G. Gate structures 160 are formed over the substrate 110. The gate structure 160 may extend along a direction Y substantially perpendicular (within process variations) to the direction X. At least one of the gate structures 160 includes a first profile (or portion) 160A overlapping the fins FS, a second profile (or portion) 160B overlapping the dielectric wall 142, and a third profile (or portion) 160C overlapping the STI structures 152. In the present embodiments, the first profile 160A has a width WA1 adjacent to the second profile 160B (or the dielectric wall 142) and a width WA2 adjacent to the third profile 160C (or the STI structures 152), and the width WA1 is greater than the width WA2. Stated differently, the first profile 160A has the width WA1 adjacent to a side of the dielectric wall 142 and the width WA2 at a position offset from the side of the dielectric wall 142, and the width WA2 is less than the width. Through the configuration, the gate structure 160 has a larger critical dimension (CD) at wall side and a less CD away from the wall side. In the context, portions of the fins FS underlying the gate structures 160 may be referred to as the channel regions. The gate structures 160 may also define a source/drain (S/D) region of the fins FS, for example, the regions of the fin FS adjacent to and on opposing sides of the channel region. A subsequent channel release process may cause the sheets have thicker portions at wall side and thinner portions away from the wall side. By covering the thicker portions of the sheets at wall-side with the gate structure 160 with larger CD, a channel length of the device at wall side is greater than a channel length of the device away from the wall side, and the device can be boosted by better short channel effect (SCE).

In some embodiments, the width WA1 is greater than the width WA2, and a difference between the width WA1 and the width WA2 is in a range from about 0.5 nanometer to about 8 nanometers. If the difference between the width WA1 and the width WA2 is less than about 0.5 nanometer, the configuration of the gate structure 160 may not boost the device. If the difference between the width WA1 and the width WA2 is greater than about 8 nanometers, the device size may be enlarged, which may resulted in limited area for source/drain contact.

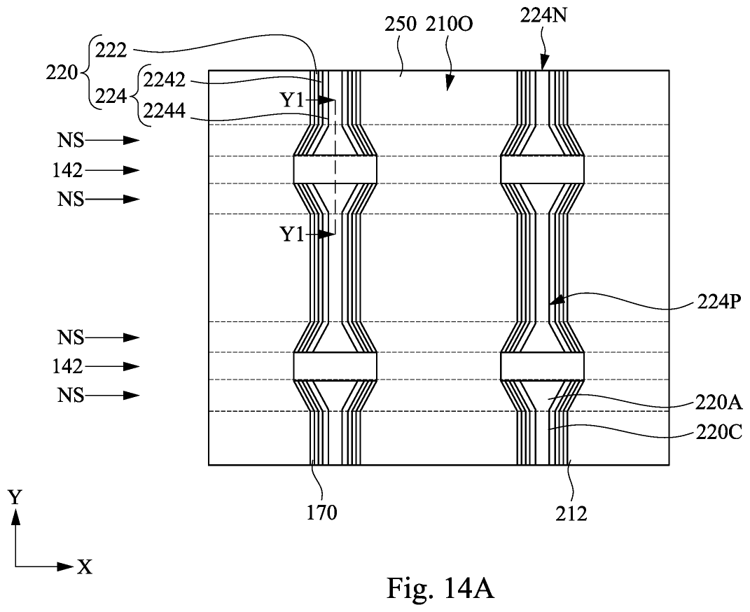

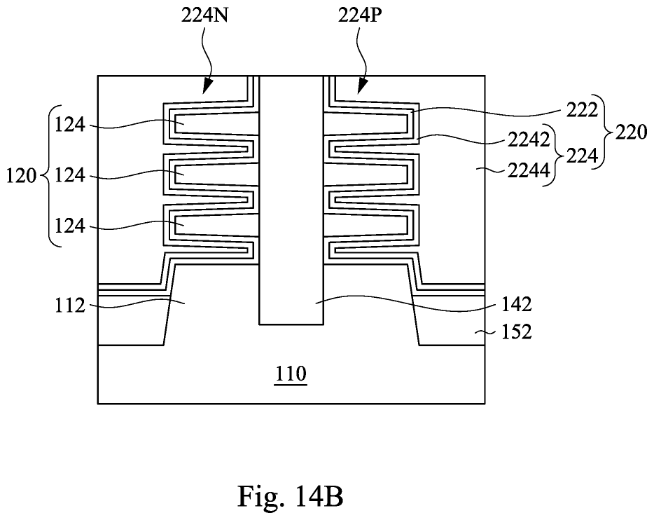

In the present embodiments, as shown in FIG. 7A, sidewalls AS of the first profiles 160A of the gate structure 160 are sloped (e.g., with respect to the directions X and Y), resulting the difference in widths of the first profiles 160A of the gate structure 160 (e.g., widths WA1 and WA2). The slope sidewalls AS may coincide with opposite straight sidewalls BS of the second profile 160B of the gate structure 160. As shown in FIG. 7A, the first and second profiles 160A and 160B of the gate structure 160 may form an octagon. In some other embodiments, the first and second profiles 160A and 160B of the gate structure 160 may form other shapes, as illustrated in FIGS. 14A-22A later. In the present embodiments, the second profile 160B may have a width WB greater than a width WC of the third profile 160C. The width WA1 of the first profile 160A may be substantially equal to the width WB of the second profile 160B, and the width WA2 of the first profile 160A may be substantially equal to the width WC of the third profile 160C. In some other embodiments, the width WB of the second profile 160B may be equal to or less than the width WC of the third profile 160C. In some other embodiments, the width WB/WC may be greater or less then the width WA1/WA2 of the first profile 160A.

In some embodiments, the gate structures 160 are dummy (sacrificial) gate structures that are subsequently removed. Thus, in some embodiments using a gate-last process, the gate structures 160 are dummy gate structures and will be replaced by the final gate structures at a subsequent processing stage of the semiconductor device. In particular, the dummy gate structures 160 may be replaced at a later processing stage by a high-k dielectric layer (HK) and metal gate electrode (MG) as discussed below.

The dummy gate structures 160 may include a gate dielectric 162, a dummy gate electrode 164, and a hard mask 166. Formation of the dummy gate structures 160 may include layer formation/deposition process, lithography process, and etching process. For example, a gate dielectric layer, a dummy gate electrode layer, and a hard mask layer are formed over the structure of FIG. 6 in a sequence. The dummy gate dielectric layer may be formed of a dielectric material such as silicon oxide, silicon nitride, a combination thereof, or the like, which may be deposited or thermally grown according to acceptable techniques. The dummy gate electrode layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. In some embodiments, the hard mask layer may be formed of a dielectric material such as silicon nitride, silicon oxynitride, silicon oxycarbide (SiOC), silicon oxycarbonitride (SiOCN), the like, or a combination thereof.

The hard mask layer is patterned into the hard mask 166 by suitable lithography and etching processes. In the lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. Subsequently, a pattern of the hard mask 166 is transferred to the dummy gate electrode layer and the gate dielectric layer by any acceptable etching technique, thereby patterning the dummy gate electrode layer and the gate dielectric layer into the dummy gate electrode 164 and gate dielectric 162. In some embodiments, the etching process may include dry etching (e.g., RIE etching), wet etching, and/or other etching methods. After the patterning process, the dummy gate electrode 164 and the gate dielectric 162 covers portions of the fins FS, which will be exposed in subsequent processes to form channel regions.

After the formation of the dummy gate structures 160, gate spacers 170 are formed on sidewalls of the dummy gate structures 160. In the present embodiments, the gate spacers 170 lines sidewalls AS, BS, and CS of the profiles 160A, 160B, and 160C of the gate structure 160, respectively. According to the shape of the gate structure 160, each of the gate spacers 170 may include a slope portion 172 over the fins FS, a vertical straight portion 174 over the dielectric wall 142, and a vertical straight portion 174 over the STI structure 152. For example, a spacer material layer is conformally deposited on the substrate using processes such as, CVD process, a subatmospheric CVD (SACVD) process, a flowable CVD process, an ALD process, a PVD process, or other suitable process. The spacer material layer may include a dielectric material such as silicon oxide, silicon nitride, silicon carbide, silicon oxynitride, SiCN films, silicon oxycarbide, SiOCN films, and/or combinations thereof. The spacer material layer is subsequently etched back to form the gate spacers 170. For example, an anisotropic etching process is performed on the deposited spacer material layer to expose portions of the fins FS not covered by the dummy gate structures 160 (e.g., in source/drain regions of the fins FS). Portions of the spacer material layer directly above the dummy gate structures 160 may be completely removed by this anisotropic etching process. In some embodiments, the spacer material layer includes multiple layers, and therefore the gate spacers 170 may be multi-layer structures.

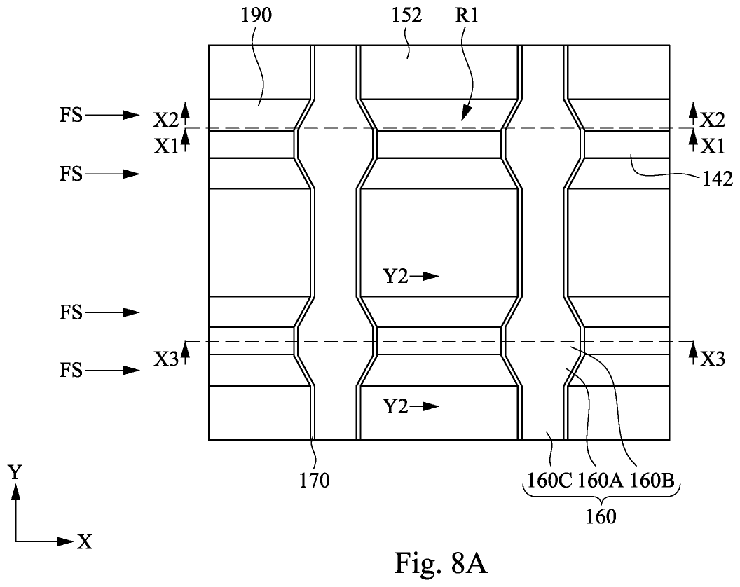

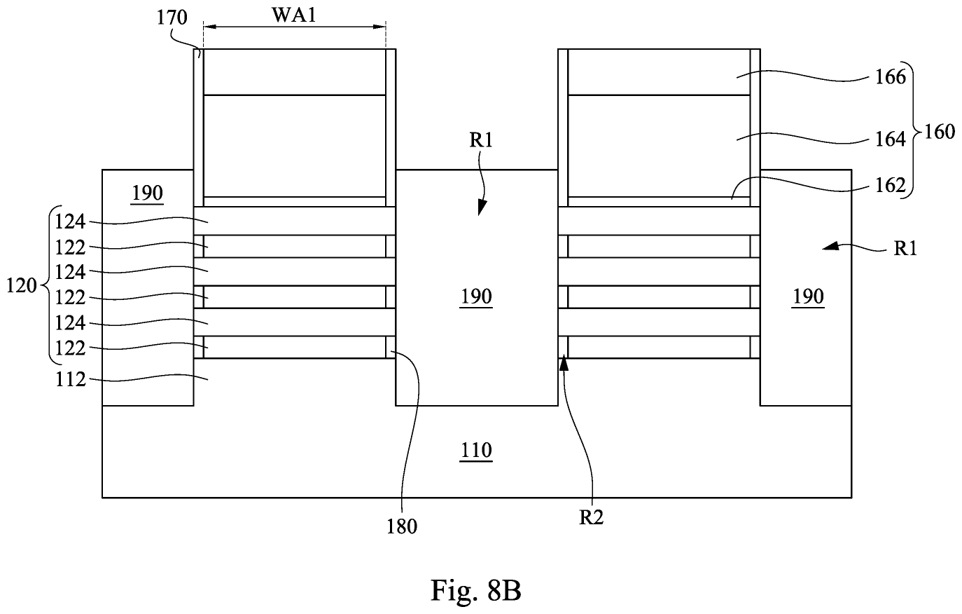

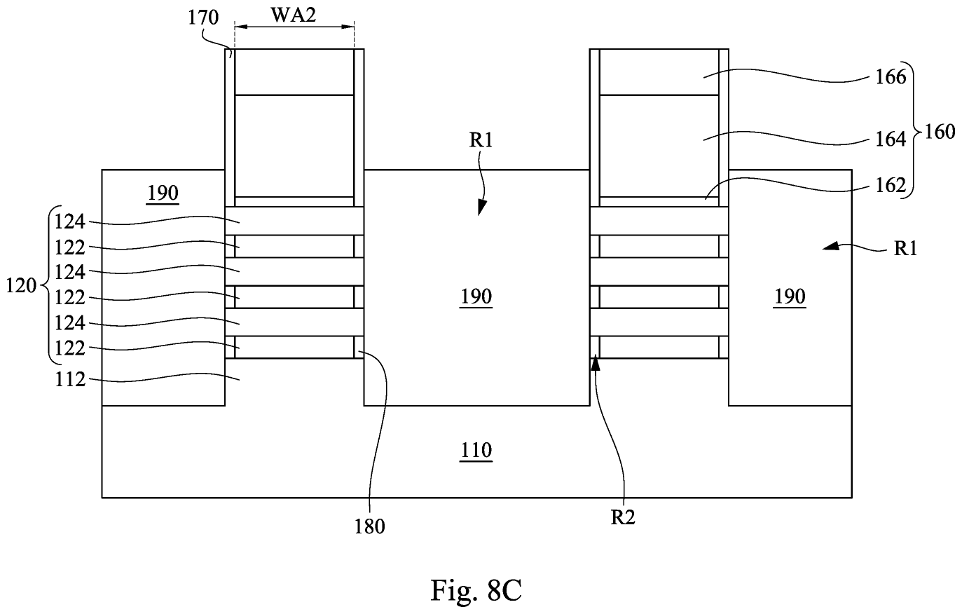

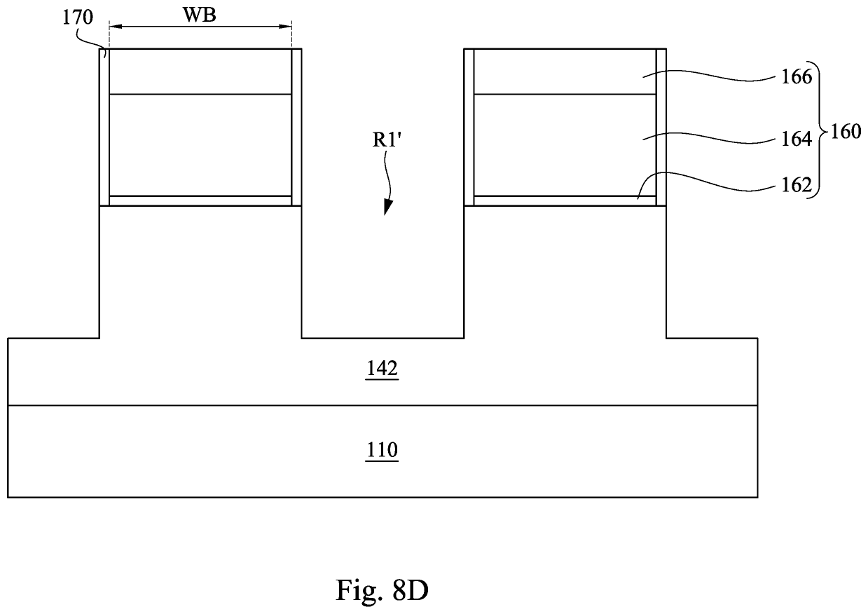

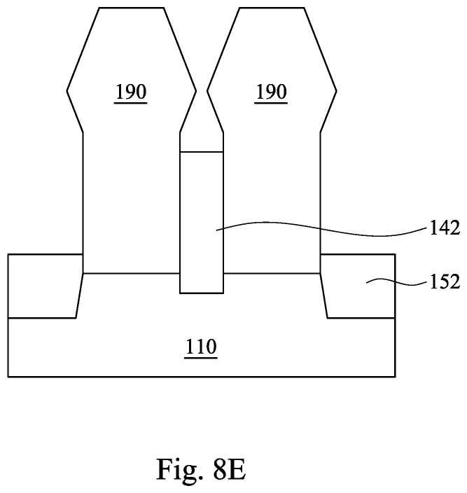

Reference is made to FIGS. 8A-8E. Exposed portions of the semiconductor fins FS that extend laterally beyond the gate spacers 170 (e.g., in source/drain regions of the fins FS) are etched by using, for example, an anisotropic etching process that uses the dummy gate structure 160 and the gate spacers 170 as an etch mask, resulting in recesses R1 into the semiconductor fins FS and between corresponding dummy gate structures 160. The recesses R1 may extend through the epitaxial layers 122 and the channel layers 124. After the anisotropic etching, end surfaces of the sacrificial layers 122 and end surfaces of channel layers 124 are exposed and aligned with respective outermost sidewalls of the gate spacers 170, due to the anisotropic etching. In some embodiments, the anisotropic etching may be performed by a dry chemical etch (e.g., reactive-ion etching) with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. In some embodiments, the etching process may also result recesses R1′ into the dielectric wall 142 and between corresponding dummy gate structures 160.

The sacrificial layers 122 are laterally or horizontally recessed by using suitable selective etching process, resulting in lateral/sidewall recesses R2 each vertically between corresponding channel layers 124. The lateral/sidewall recesses R2 may alternate with the channel layers 124. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The channel layers 124 may have a higher etch resistance to the etching process than that of the epitaxial layers 122. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 124 is not significantly etched by the process of laterally recessing the sacrificial layers 122. As a result, the channel layers 124 laterally extend past opposite end surfaces of the sacrificial layers 122.

Inner spacers 180 are formed in the recesses R2. Formation of the inner spacers 180 includes depositing an inner spacer material layer to fill the lateral/sidewall recesses R2, and performing an anisotropic etching process to trim the deposited inner spacer material layer. The remaining portions of the deposited inner spacer material layer are denoted as inner spacers 180. The inner spacers 180 may include a low-k dielectric material, such as SiOₓ, SiON, SiOC, SiN, SiCN, or SiOCN, and may be formed by a suitable deposition method, such as ALD. The inner spacers 180 may serve to isolate metal gates from source/drain regions formed in subsequent processing.

Source/drain epitaxial structures 190 are formed in the recesses R1 on opposite sides of the channel layers 124 and on opposite sides of the dummy gate structure 160. The source/drain epitaxial structures 190 connects the channel layers 124. In some embodiments, the source/drain epitaxial structures 190 may include Ge, Si, GaAs, AlGaAs, SiGe, GaAsP, SiP, or other suitable material. The source/drain epitaxial structures 190 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 190 are not in-situ doped, an implantation process (i.e., a junction implant process) is performed to dope the source/drain epitaxial structures 190. The source/drain epitaxial structures 190 may be formed by performing an epitaxial growth process that provides an epitaxial material on the exposed surfaces of the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the substrate portion 112 and the channel layers 124 of the fins FS.

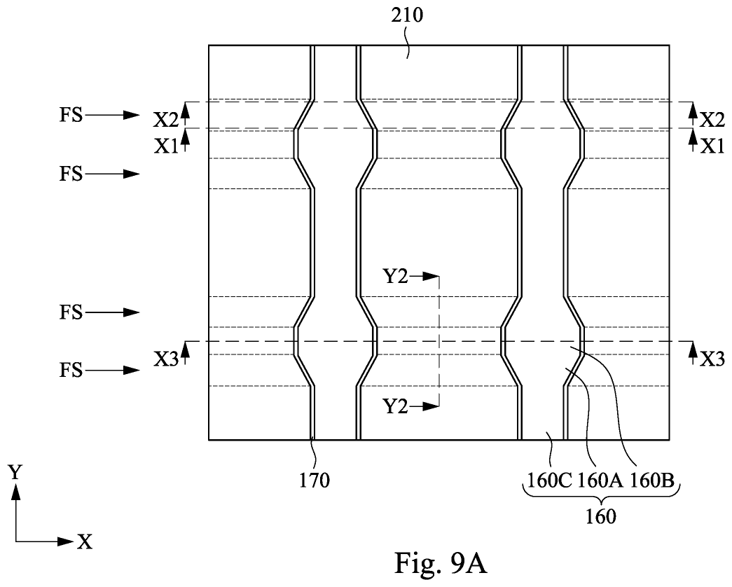

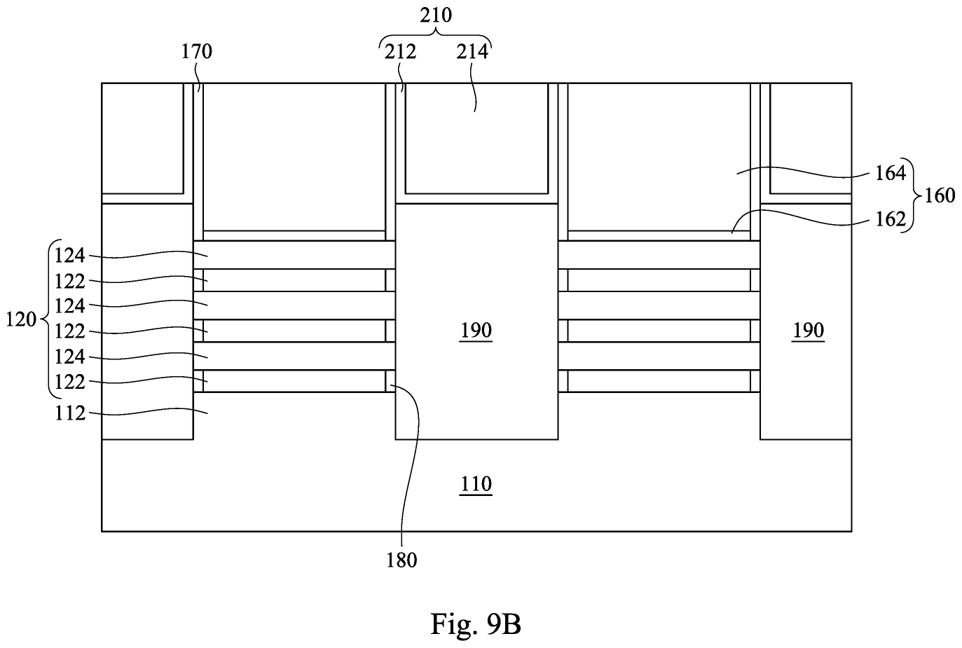

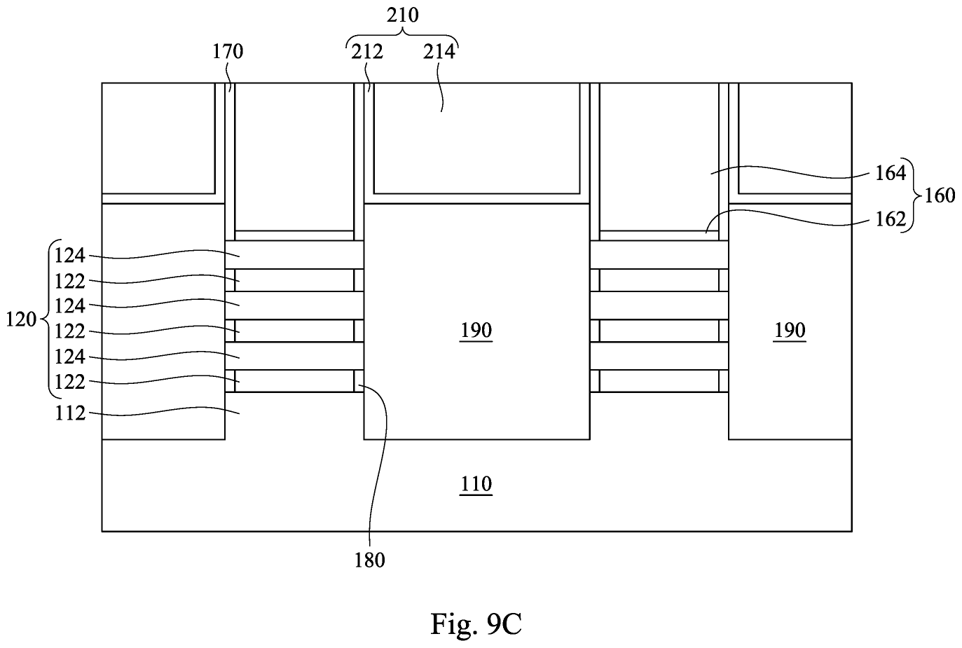

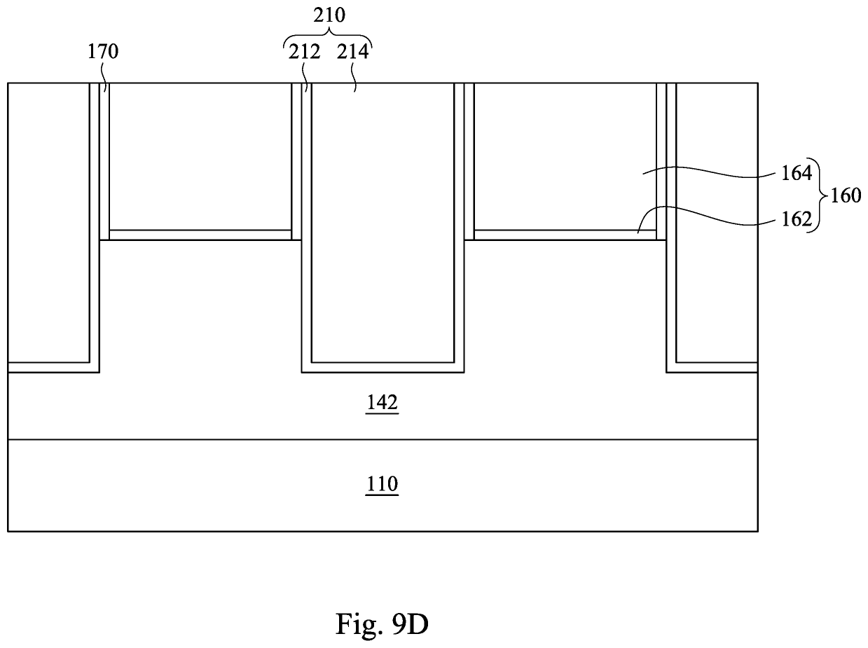

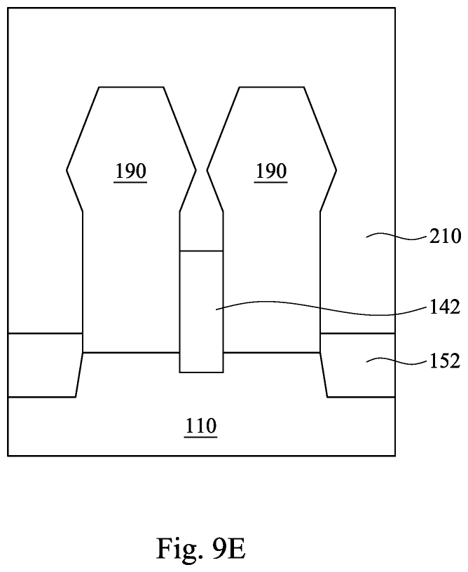

Reference is made to FIGS. 9A-9E. A dielectric material 210 is formed over the substrate 110 and filling the space between the dummy gate structures 160. In some embodiments, the dielectric material 210 includes a contact etch stop layer (CESL) 212 and an interlayer dielectric (ILD) layer 214 formed in sequence. In some examples, the CESL 212 includes a silicon nitride layer, silicon oxide layer, a silicon oxynitride layer, and/or other suitable materials having a different etch selectivity than the ILD layer 214. The CESL 212 may be formed by plasma-enhanced chemical vapor deposition (PECVD) process and/or other suitable deposition or oxidation processes. The ILD layer 214 is then deposited over the CESL 212. In some embodiments, the ILD layer 214 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 212. The ILD layer 214 may be deposited by a PECVD process or other suitable deposition technique. In some embodiments, after formation of the ILD layer 214, the semiconductor device may be subject to a high thermal budget process to anneal the ILD layer 214. After depositing the ILD layer 214, a planarization process may be performed to remove excessive materials of the ILD layer 214. For example, a planarization process includes a chemical mechanical planarization (CMP) process which removes portions of the ILD layer 214 and the CESL layer 212 overlying the dummy gate structures 160 and planarizes a top surface of the semiconductor device.

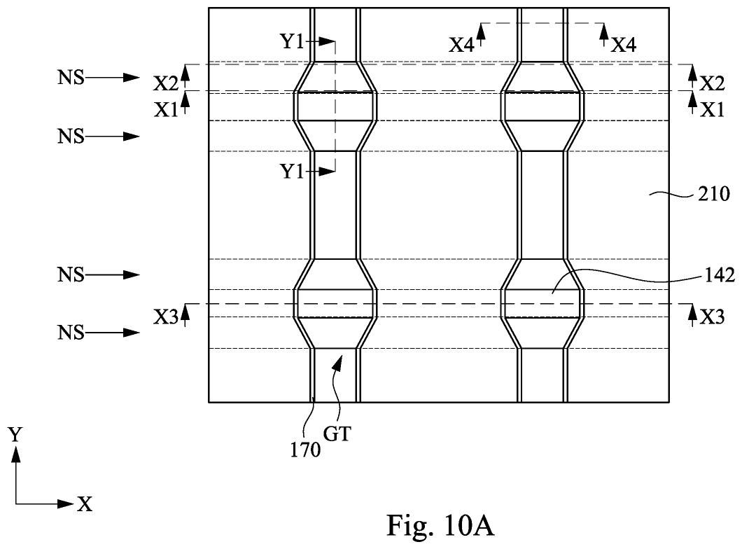

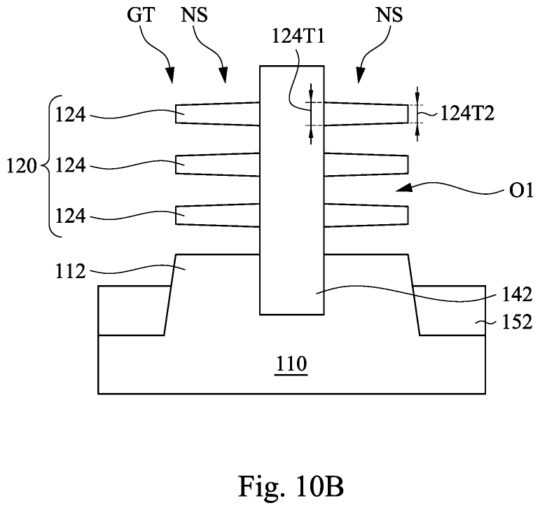

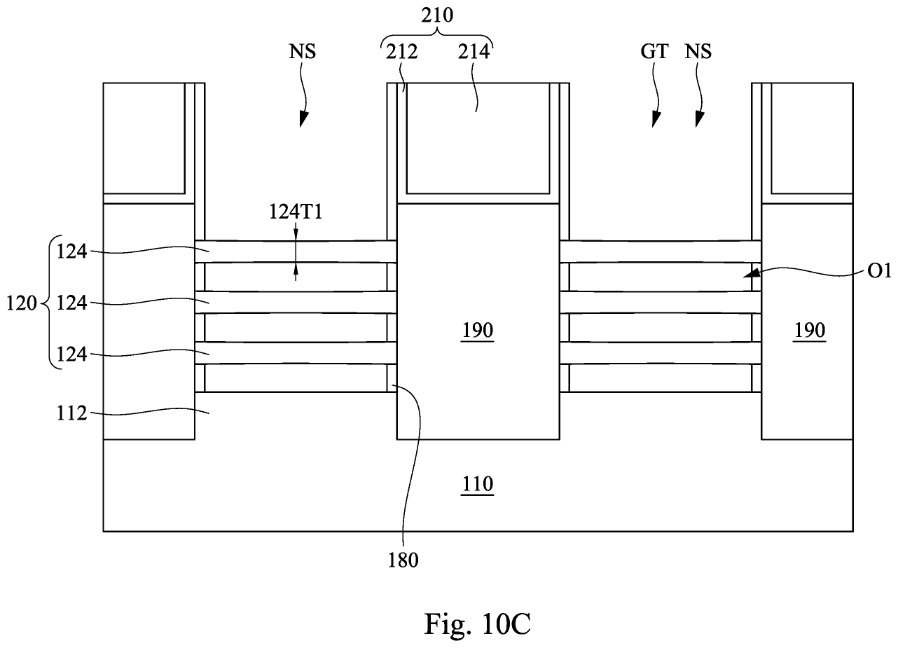

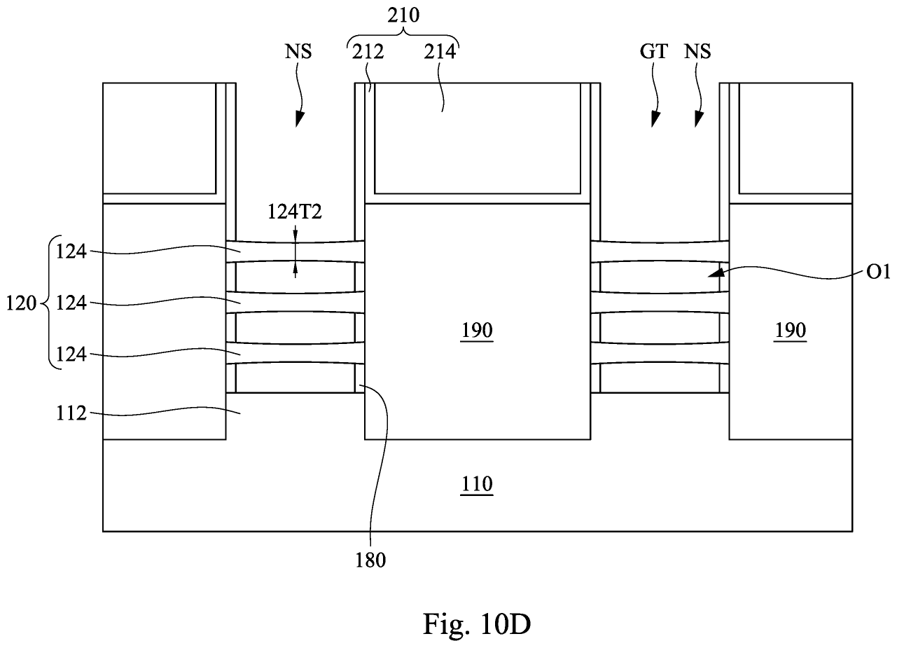

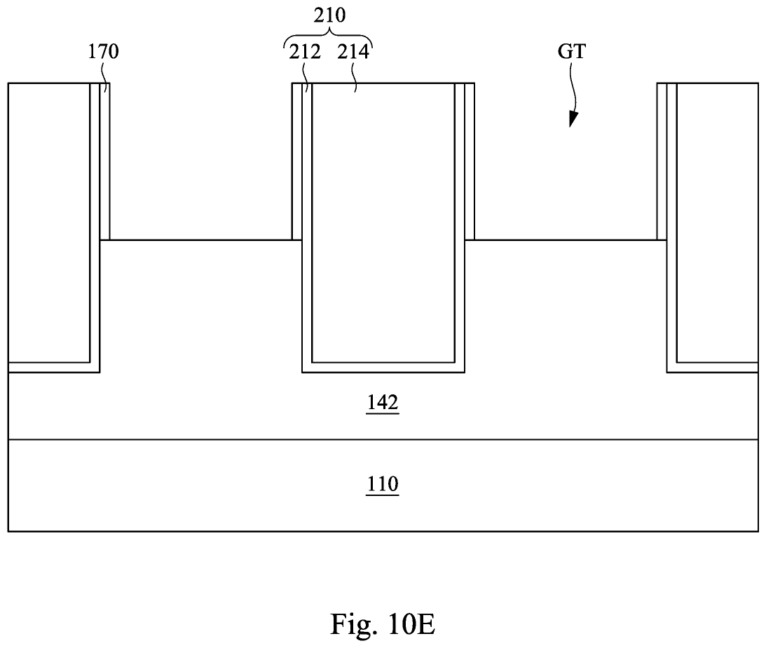

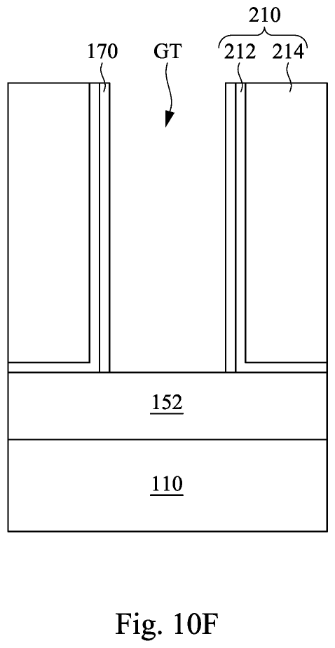

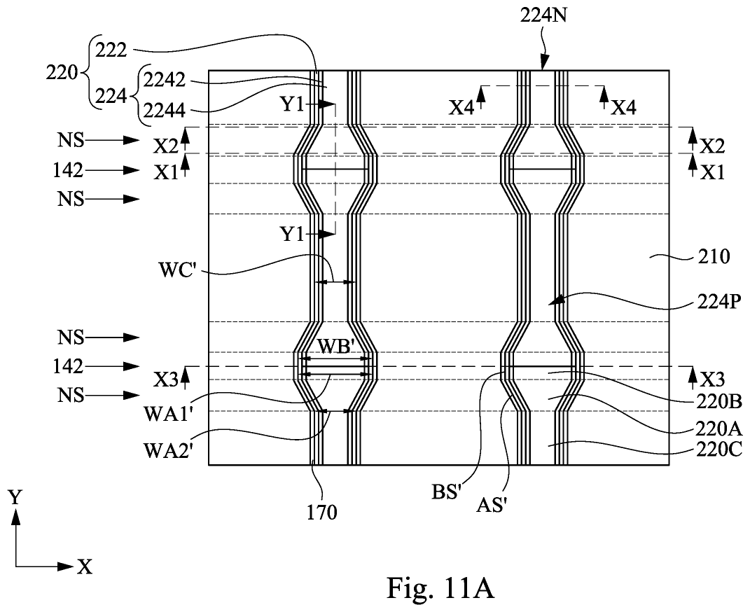

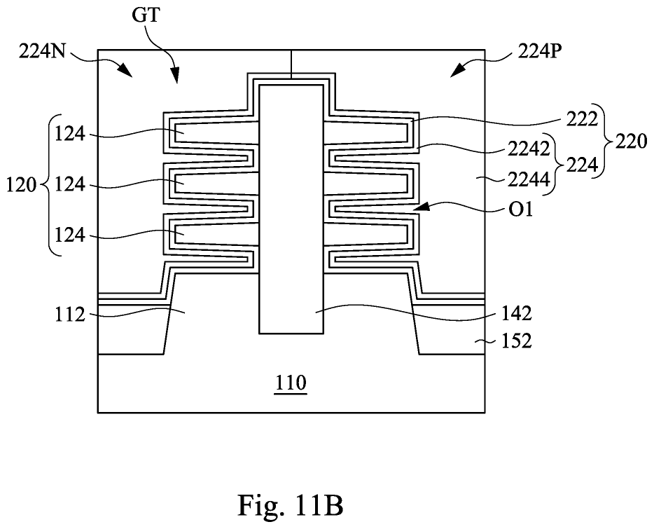

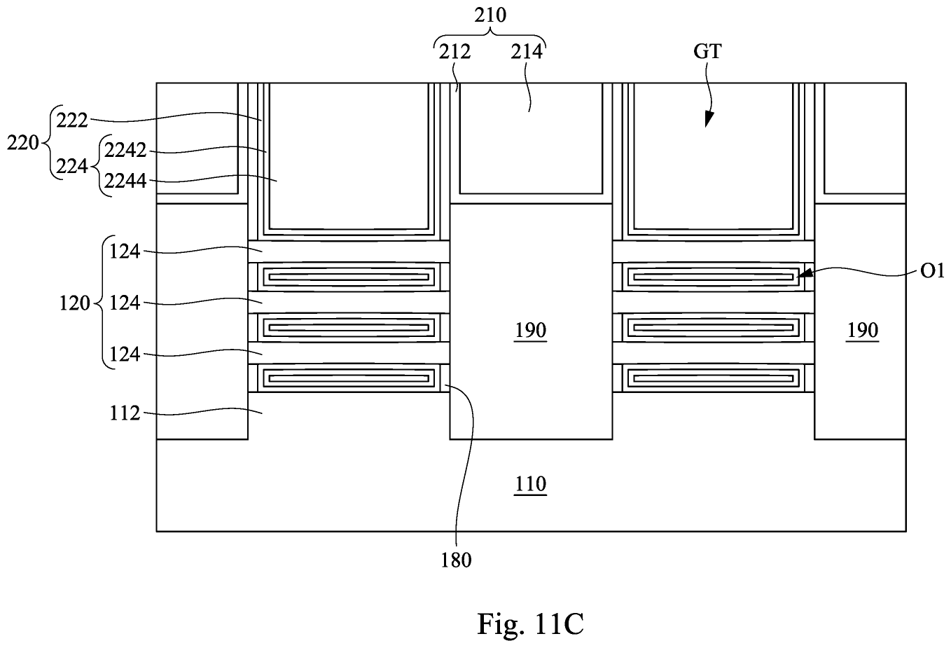

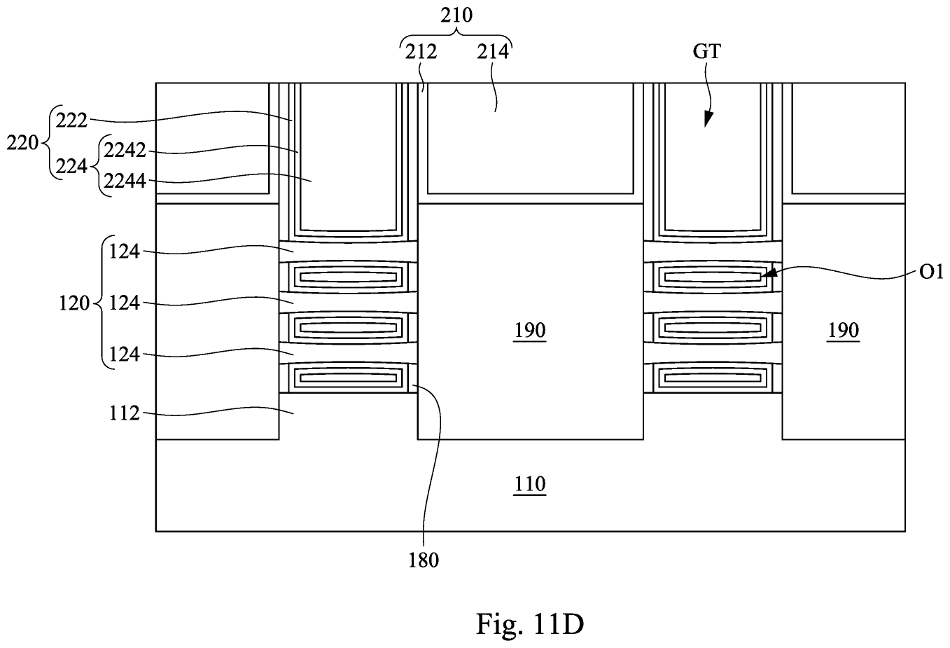

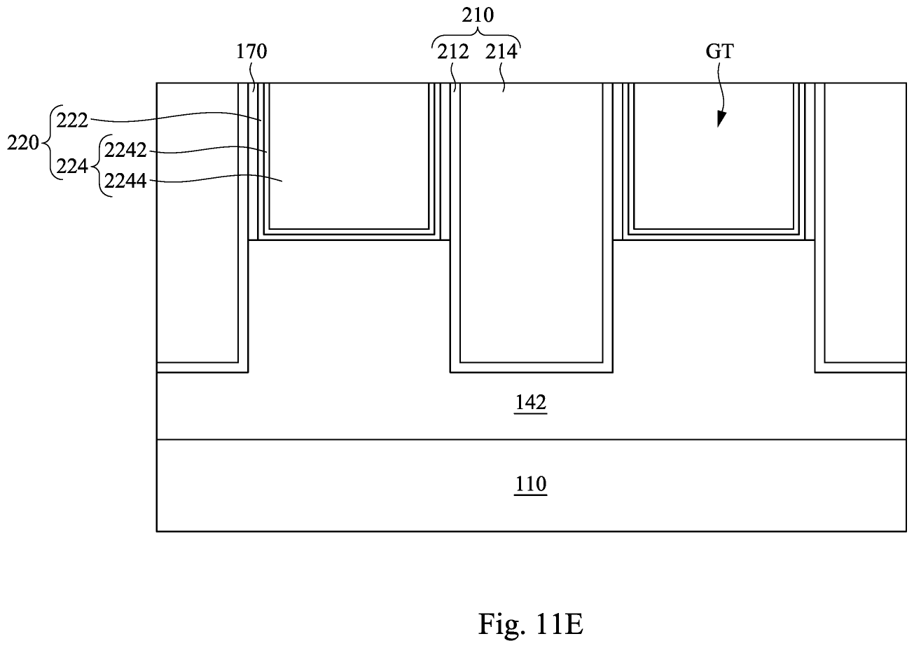

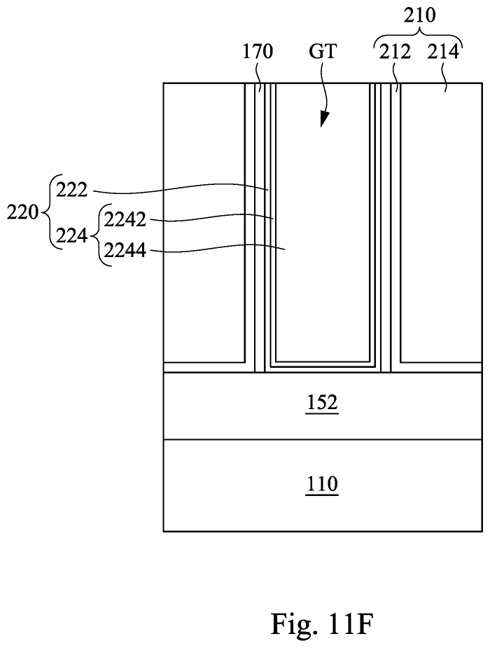

FIG. 10A-11F shows a gate replacement process. The dummy gate structures 160 and the sacrificial layers 122 (referring to FIGS. 9A-9E) are replaced with high-k/metal gate structures 220. Reference is made to FIGS. 10A-10F. The dummy gate structures 160 (referring to FIGS. 9A-9E) are removed, followed by removing the sacrificial layers 122 (referring to FIGS. 9A-9E). In the illustrated embodiments, the dummy gate structures 160 (referring to FIGS. 9A-9E) are removed by using a selective etching process (e.g., selective dry etching, selective wet etching, or a combination thereof) that etches the materials in dummy gate structures 160 (referring to FIGS. 9A-9E) at a faster etch rate than it etches other materials (e.g., gate spacers 170, and/or the dielectric material 210), thus resulting in gate trenches GT between corresponding gate spacers 170, with the sacrificial layers 122 (referring to FIGS. 9B and 9C) exposed in the gate trenches GT. Subsequently, the sacrificial layers 122 (referring to FIGS. 9B and 9C) in the gate trenches GT are etched by using another selective etching process that etches the sacrificial layers 122 at a faster etch rate than it etches the channel layers 124, thus forming openings/spaces O1 between neighboring channel layers 124. The openings/spaces O1 may expose the sidewalls of the inner spacers 180. In this way, the channel layers 124 become nanosheets suspended over the substrate 110 and between the source/drain epitaxial structures 190. According to the pattern of fins FS (referring to FIG. 9A), plural subsects of channel layers 124 (denoted as nanosheet subsets NS) remain over the substrate 110. This step is also called a channel release process. The channel release process is performed to leave a first nanosheet subset NS on a first side of the dielectric wall 142 and a second nanosheet subset NS on a second side of the dielectric wall 142. At this interim processing step, the openings/spaces O1 between nanosheets 124 may be filled with ambient environment conditions (e.g., air, nitrogen, etc).

In some embodiments, the sacrificial layers 122 (referring to FIGS. 9B and 9C) are removed by using a selective dry etching process. In some embodiments, the sacrificial layers 122 (referring to FIGS. 9B and 9C) are SiGe and the channel layers 124 are silicon allowing for the selective removal of the sacrificial layers 122 (referring to FIGS. 9B and 9C). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until a desired amount of the sacrificial layer 122 is laterally removed.

In the present embodiments, with the dielectric wall 142 in place, during the selective dry etching process, the channel layers 124 adjacent to the dielectric wall 142 may be consumed less than the channel layers 124 away from the dielectric wall 142. For example, after the selective dry etching process, the channel layers 124 extends from a side surface of the dielectric wall 142, the channel layers 124 may have a first side interfacing the dielectric wall 142 and a second side facing away from the dielectric wall 142, and the channel layers 124 is thicker at the first side than at the second side. For example, the channel layers 124 have a thickness 124T1 adjacent to the dielectric wall 142 and a thickness 124T2 away from the dielectric wall 142, and the thickness 124T2 is less than the thickness 124T1.

Reference is made to FIGS. 11A-11F. Replacement gate structures 220 are respectively formed in the gate trenches GT to surround each of the nanosheets 124 suspended in the gate trenches GT. The gate structures 220 may be final gates of GAA FETs. The final gate structure may be a high-k/metal gate stack, however other compositions are possible. In some embodiments, each of the gate structures 220 forms the gate associated with the multi-channels provided by the plurality of nanosheets 124. For example, the high-k/metal gate structures 220 are formed within the openings/spaces O1 provided by the release of nanosheets 124. The high-k/metal gate structures 220 may be between the nanosheets 124 and surrounded by the inner spacers 180.

The high-k/metal gate structures 220 may inherit the shape of the dummy gate structures 160 (referring to FIG. 9A). For example, the high-k/metal gate structure 220 includes a first 220A overlapping the nanosheet subsets NS, a second profile (or portion) 220B overlapping the dielectric wall 142, and a third profile (or portion) 220C overlapping the STI structures 152. In the present embodiments, the first profile 220A has a width WA1′ adjacent to the second profile 220B (or the dielectric wall 142) and a width WA2′ adjacent to the third profile 160C (or the STI structures 152), and the width WA1′ is greater than the width WA2′. Through the configuration, the gate structure 220 has a larger CD at wall side and a less CD away from the wall side. As the channel release process may cause the sheets have thicker portions at wall side and thinner portions away from the wall side. By covering the thicker portions of the sheets at wall-side with the gate structure 220 with larger CD, the device can be boosted by better SCE.

In the present embodiments, as shown in FIG. 11A, sidewalls AS' of the first profiles 220A of the gate structure 220 are sloped, resulting the difference in widths of the first profiles 220A of the gate structure 220 (e.g., widths WA1′ and WA2′). The slope sidewalls AS' may coincide with opposite straight sidewalls BS' of the second profile 220B of the gate structure 220. As shown in FIG. 11A, the first and second profiles 220A and 220B of the gate structure 220 may form an octagon. In some other embodiments, the first and second profiles 220A and 220B of the gate structure 220 may form other shapes, as illustrated in FIGS. 14B-22B later. In the present embodiments, the second profile 220B may have a width WB′ substantially equal to the width WA1′ of the first profile 220A. In some other embodiments, the width WB′ may be greater or less then the width WA1′ of the first profile 220A. In the present embodiments, the third profile 220C may have a width WC′ substantially equal to the width WA2′ of the first profile 220A. In some other embodiments, the width WC′ may be greater or less then the width WA2′ of the first profile 220A.

In various embodiments, the high-k/metal gate structure 220 includes a gate dielectric layer 222 formed around the nanosheets 124 and a gate metal layer 224 formed around the gate dielectric layer 222 and filling a remainder of gate trenches GT. Formation of the high-k/metal gate structures 220 may include one or more deposition processes to form various gate materials, followed by a CMP process to remove excessive gate materials, resulting in the high-k/metal gate structures 220 having top surfaces level with a top surface of the dielectric material 210. In the present embodiments, the CMP process is performed such that the top surfaces of the high-k/metal gate structures 220 is higher than a top surface of the dielectric wall 142. In some other embodiments, the CMP process is performed such that the top surfaces of the high-k/metal gate structures 220 is level with the top surface of the dielectric wall 142. Thus, transistors (e.g., GAA FET) are formed, and the high-k/metal gate structure 220 surrounds each of the nanosheets 124, and thus is referred to as a gate of the transistors (e.g., GAA FET).

The gate dielectric layer 222 may include an interfacial layer and a high-k gate dielectric layer over the interfacial layer. In some embodiments, the interfacial layer is silicon oxide formed on exposed surfaces of semiconductor materials in the gate trenches GT by using, for example, thermal oxidation, chemical oxidation, wet oxidation or the like. As a result, surface portions of the nanosheets 124 and the substrate 110 exposed in the gate trenches GT are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 224 includes one or more metal layers. For example, the gate metal layer 224 may include one or more work function metal layers 2242 stacked one over another and a fill metal 2244 filling up a remainder of gate trenches GT. The one or more work function metal layers 2242 in the gate metal layer 224 provide a suitable work function for the high-k/metal gate structures 220. The gate metal layer 224 is denoted as gate metal layers 224N and 224P for n-type devices and p-type devices, respectively. For an n-type GAA FET, the gate metal layer 224N may include one or more n-type work function metal (N-metal) layers 2242. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, titanium nitride (TiN), tungsten (W), and/or other suitable materials. On the other hand, for a p-type GAA FET, the gate metal layer 224P may include one or more p-type work function metal (P-metal) layers 2242. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the gate metal layers 224N and 224P may include the same work function metal layers 2242 for n-type devices and p-type devices. In some embodiments, the gate metal layers 224N and 224P may include different work function metal layers 2242 for n-type devices and p-type devices. In some embodiments, the fill metal 2244 in the gate metal layer 224 (e.g., the gate metal layer 224N and/or 224P) may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. The gate metal layers 224N and 224P may include the same fill metal 2244 for n-type devices and p-type devices.

In some embodiments, the high-k/metal gate structure 220 including the gate metal layers 224N and the high-k/metal gate structure 220 including the gate metal layers 224P may have similar profile. For example, over the nanosheets, the high-k/metal gate structure 220 including the gate metal layers 224N and the high-k/metal gate structure 220 including the gate metal layers 224P have the width WA1′ greater than the width WC′.

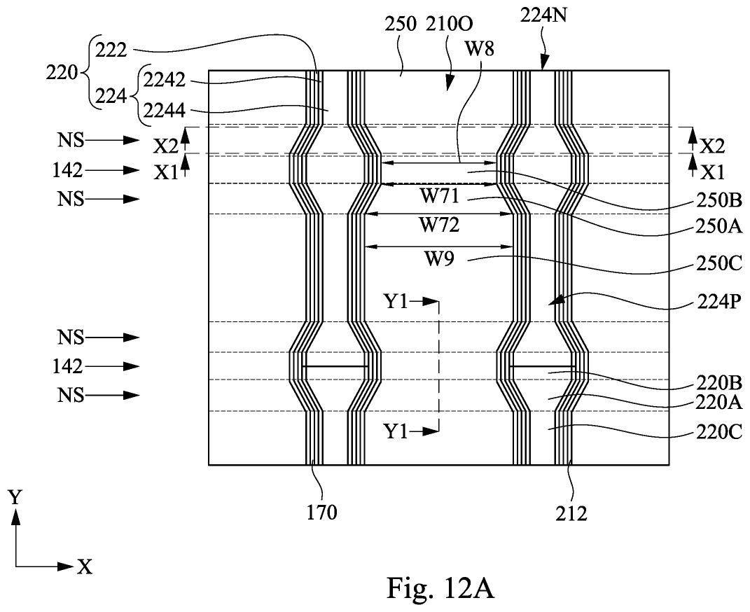

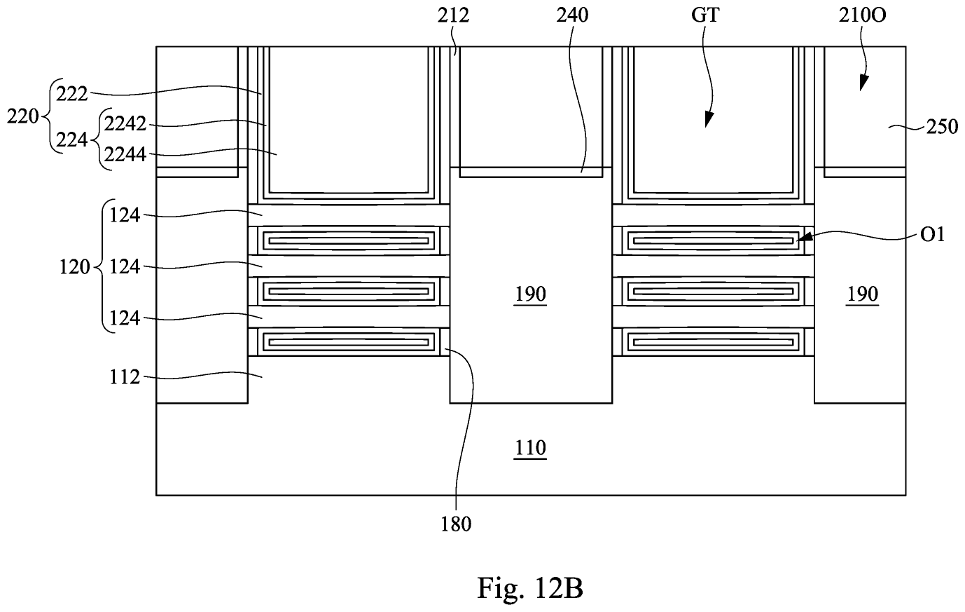

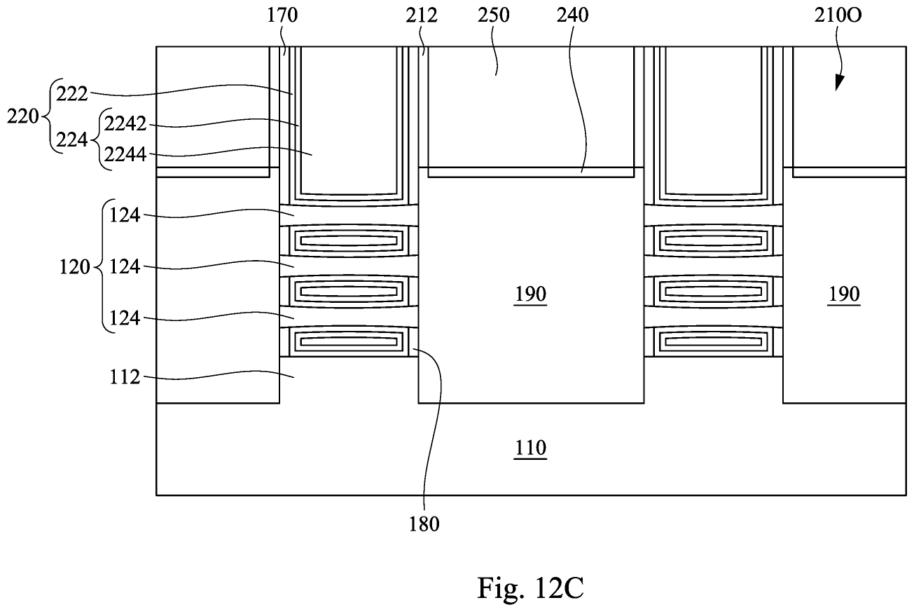

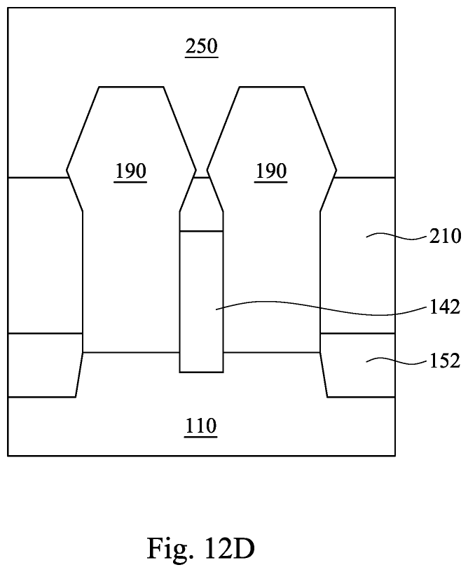

Reference is made to FIGS. 12A-12D. Source/drain contacts 250 are formed over the source/drain epitaxial structures 190. In some embodiments, source/drain contact openings 2100 are first formed through the dielectric material 210 to expose the source/drain epitaxial structures 190 by suitable patterning process (e.g., using suitable photolithography and etching techniques). Subsequently, silicide regions 240 are formed on the exposed side of the source/drain epitaxial structures 190 by using a silicidation process, followed by forming source/drain contacts 250 over the silicide regions 240. Silicidation may be formed by depositing a metal layer (e.g., nickel layer or cobalt layer) over the exposed source/drain epitaxial structures 190, annealing the metal layer such that the metal layer reacts with silicon (and germanium if present) in the source/drain epitaxial structures 190 to form the metal silicide region 240 (e.g., nickel silicide or cobalt silicide), and thereafter removing the non-reacted metal layer. Source/drain contacts 250 may be formed by depositing one or more metal materials (e.g., tungsten, cobalt, copper, the like or combinations thereof) to fill the contact holes by using suitable deposition techniques (e.g., CVD, PVD, ALD, the like or combinations thereof), followed by a CMP process to remove excess metal materials outside the contact openings 2100.

In the present embodiments, the source/drain contacts 250 may be arranged according to the configuration of gate structure 220, thereby keeping isolated from each other by low-k dielectrics. The source/drain contacts 250 may have a first portion 250A over the nanosheet subsets NS, a second portion 250B over the dielectric wall 142, and a third portion 250C over the STI structures 152. As shown in figure, the first portion 250A has a width W71 adjacent to the dielectric wall 142 and a width W72 adjacent to the STI structures 152, the second portion 250B has a width W8, and the third portion 250C has the width W9. In the present embodiments, the width W71 of the first portion 250A is less than the second width W72 of the first portion 250A, the width W71 of the first portion 250A is substantially equal to the width W8 of the second portion 250B, and the width W72 of the first portion 250A is substantially equal to the width W9 of the third portion 250C. In other embodiments, these widths may be designed in various ways according to the configuration of gate structure 220.

The source/drain contacts 250 may have non-linear sidewalls. For example, in FIG. 12A, the non-linear sidewall of the source/drain contact 250 has a recessed profile over the dielectric wall 142. In some embodiments, the recessed profile of the source/drain contact 250 is also over the one or more semiconductor channels.

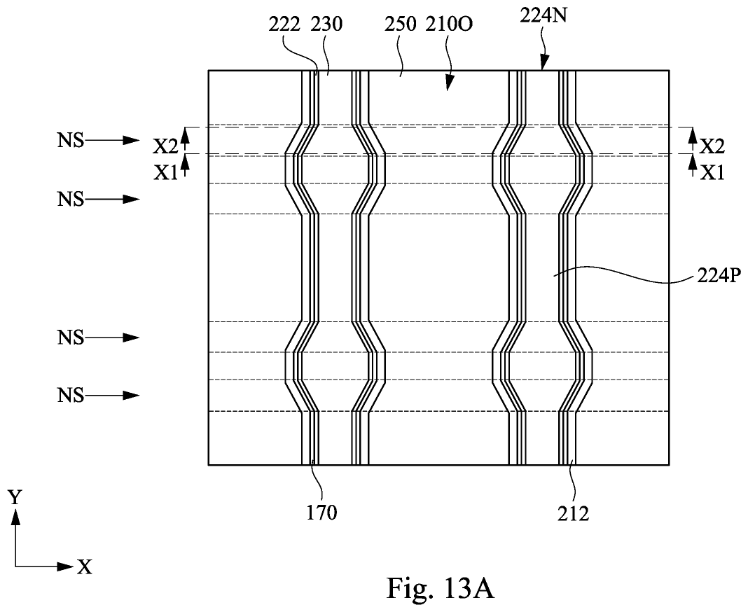

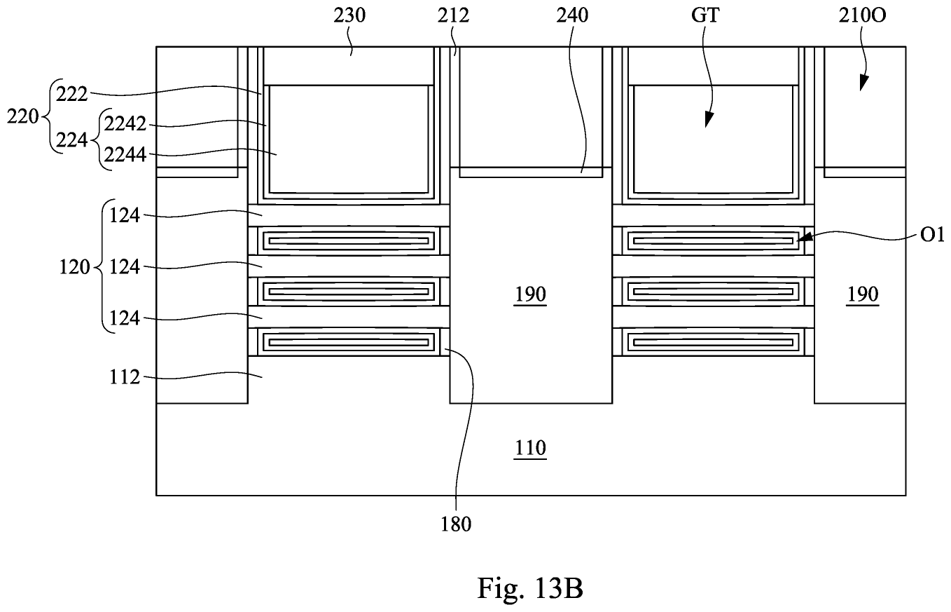

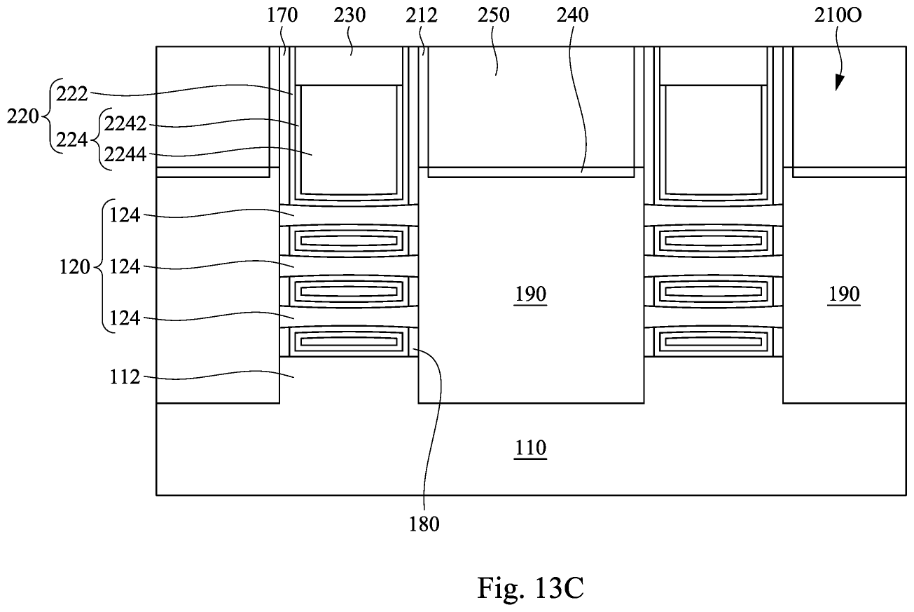

FIGS. 13A-13C illustrate schematic views of a semiconductor device in accordance with some embodiments of the present disclosure. FIG. 13A is a top view of the semiconductor device in accordance with some embodiments. FIG. 13B is a cross-sectional view of the semiconductor device taken along line X1-X1 of FIG. 13A. FIG. 13C is a cross-sectional view of the semiconductor device taken along line X2-X2 of FIG. 13A. Details of the present embodiments are similar to those illustrated in the embodiments of FIG. 1-12D, except that the source/drain contacts 250 are formed by a self-aligned process. In the present embodiments, protection layers 230 are first formed over the gate structures 220. Formation of the protection layers 230 includes recessing top surfaces of the gate structures 220, depositing suitable protective material over the recessed top surfaces of the gate structures 220. In some embodiments, the protection material includes SiN, SiCN, SiOC, SiOCN or the like. A planarization process is performed to remove excess portions of the protective material and planarize a top surface of the semiconductor device. Remaining portions of the protective material form the protection layers 230.

Source/drain contact openings 2100 are then formed through the dielectric material 210 to expose the source/drain epitaxial structures 190 by an etching back process. The etching back process etches the dielectric material 210 faster than etches the protection layers 230, such that the gate structure 220 underlying the protection layers 230 are not substantially damaged during the etching back process. Subsequently, silicide regions 240 are formed on the exposed side of the source/drain epitaxial structures 190 by using a silicidation process, followed by forming source/drain contacts 250 over the silicide regions 240. Other details of the present embodiments are similar to those illustrated in the embodiments of FIG. 1-12D, and thereto not repeated herein.

FIGS. 14A-14B illustrate schematic views of a semiconductor device in accordance with some embodiments of the present disclosure. FIG. 14A is a top view of the semiconductor device in accordance with some embodiments. FIG. 14B is a cross-sectional view of the semiconductor device taken along line Y1-Y1 of FIG. 14A. Details of the present embodiments are similar to those illustrated in the embodiments of FIG. 1-12D, except that the CMP process may be performed until reach the dielectric material 210, such that the top surface of the dielectric material 210 is exposed, and the top surface of the high-k/metal gate structures 220 is level with the top surface of the dielectric material 210. As a result, the high-k/metal gate structures 220 may have the profiles 220A over the nanosheet subsets NS and the profiles 220C over the STI structures 152, but not include the profile 220B (referring to FIGS. 1-12D) over the dielectric wall 142. Through the configuration, the n-type devices (or the gate metal layers 224N) and p-type devices (or the gate metal layers 224P) are spaced apart from each other by the dielectric wall 142. Other details of the present embodiments are similar to those aforementioned, and thereto not repeated herein.

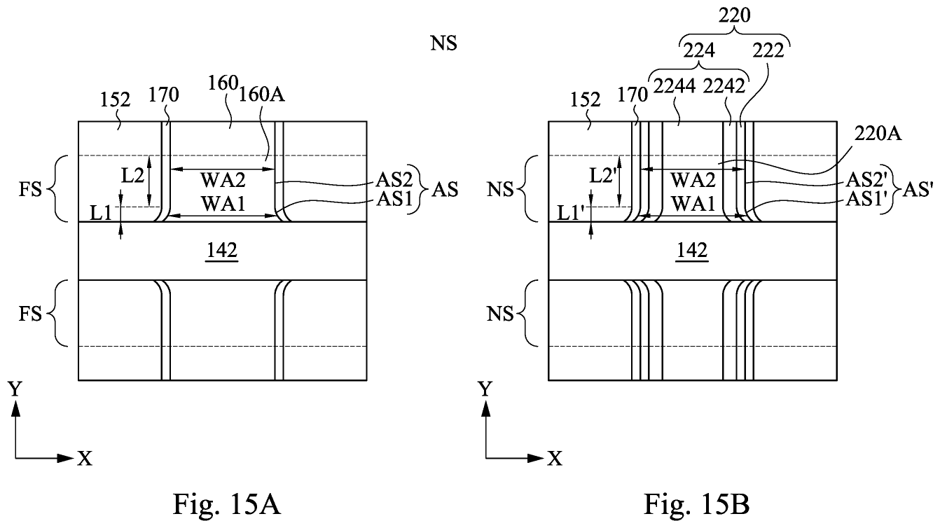

FIGS. 15A and 15B illustrate top views of intermediate stages in the manufacture of a semiconductor device in accordance with some embodiments of the present disclosure. Details of the present embodiments are similar to those illustrated above, except that the first profiles 160A of the dummy gate structure 160 overlapping the nanosheet subsets NS have a shape different from those illustrated in the embodiments of FIGS. 1-12D. For example, referring to FIG. 15A, each of the sidewalls AS of the first profiles 160A of the gate structure 160 has a curved portion AS1 adjacent to the dielectric wall 142 and a vertical straight portion AS2 away from the dielectric wall 142.

In the present embodiments, the curved portions AS1 of the sidewalls AS curve outwards, which in turn may result in that the width WA1 of the first profile 160A adjacent to the dielectric wall 142 is greater than the width WA2 of the first profile 160A adjacent to the STI structures 152. Through the configuration, the gate structure 160 has a larger CD at wall side and a less CD away from the wall side. When a channel release process may cause the sheets have thicker portions at wall side and thinner portions away from the wall side, by covering the thicker portions of the sheets at wall-side with the gate structure 160 with larger CD, the device can be boosted by better SCE.

In the present embodiments, a first length L1 of the curved portion AS1 measured along the direction Y is less than a second length L2 of the vertical straight portion AS2 measured along the direction Y. In some other embodiments, the first length L1 of the curved portion AS1 measured along the direction Y may be greater than or equal to the second length L2 of the vertical straight portion AS2 measured along the direction Y.

In FIG. 15B, the dummy gate structures 160 (referring to FIG. 15A) are replaced with high-k/metal gate structures 220. The high-k/metal gate structures 220 may inherit the shape of the dummy gate structures 160 (referring to FIG. 15A). For example, the gate structure 220 have the first profiles 220A overlapping the nanosheet subsets NS. As aforementioned, the first profile 220A has a width WA1′ adjacent to the dielectric wall 142 and a width WA2′ adjacent to the STI structures 152, and the width WA1′ is greater than the width WA2′. In the present embodiments, each of the sidewalls AS' of the first profiles 220A of the gate structure 220 has a curved portion AS1′ adjacent to the dielectric wall 142 and a vertical straight portion AS2′ away from the dielectric wall 142. In some examples, a first length L1′ of the curved portion AS1′ measured along the direction Y is less than a second length L2′ of the vertical straight portion AS2′ measured along the direction Y. In some other examples, the first length L1′ of the curved portion AS1′ measured along the direction Y is greater than or equal to the second length L2′ of the vertical straight portion AS2′ measured along the direction Y. Other details of the present embodiments are similar to those illustrated above, and therefore not repeated herein.

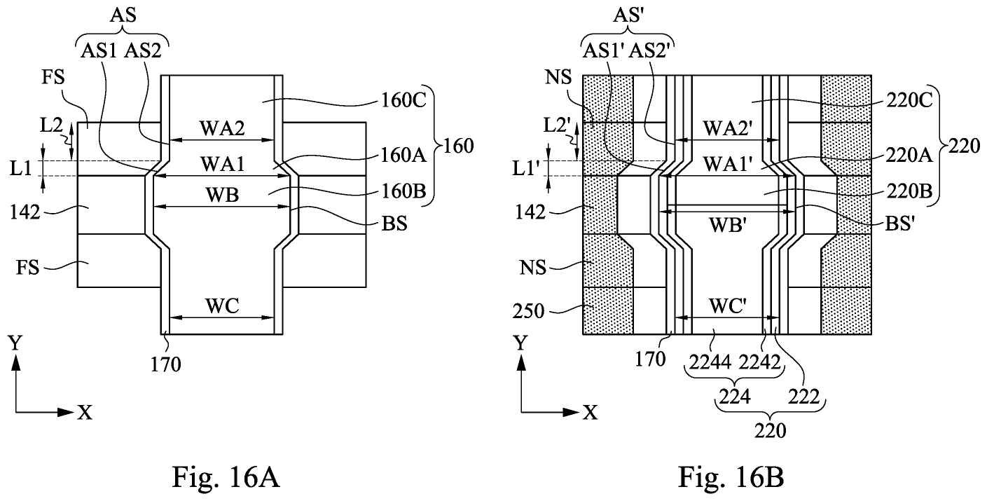

FIGS. 16A and 16B illustrate top views of intermediate stages in the manufacture of a semiconductor device in accordance with some embodiments of the present disclosure. Details of the present embodiments are similar to those illustrated above, except that the first profiles 160A of the dummy gate structure 160 overlapping the nanosheet subsets NS have a shape different from those illustrated in the previous embodiments. For example, referring to FIG. 16A, each of the sidewalls AS of the first profiles 160A of the gate structure 160 has a slope portion AS1 adjacent to the dielectric wall 142 and a vertical straight portion AS2 away from the dielectric wall 142. In the present embodiments, the second profile 160B over the dielectric wall 142 may have a width WB greater than a width WC of the third profile 160C over the STI structure. The first profile 160A of the gate structure 160 connects the second profile 160B of the gate structure 160 over the dielectric wall 142 to the third profile 160C of the gate structure 160. The width WA1 of the first profile 160A may be substantially equal to the width WB of the second profile 160B, and the width WA2 of the first profile 160A may be substantially equal to the width WC of the third profile 160C.

Through the design of the slope portions AS1 of the sidewalls AS, the width WA1 of the first profile 160A adjacent to the dielectric wall 142 is greater than the width WA2 of the first profile 160A adjacent to the STI structures 152. Through the configuration, the gate structure 160 has a larger CD at wall side and a less CD away from the wall side. When a channel release process may cause the sheets have thicker portions at wall side and thinner portions away from the wall side, by covering the thicker portions of the sheets at wall-side with the gate structure 160 with larger CD, the device can be boosted by better SCE.

In the present embodiments, a first length L1 of the slope portion AS1 measured along the direction Y is less than a second length L2 of the vertical straight portion AS2 measured along the direction Y. In some other embodiments, the first length L1 of the slope portion AS measured along the direction Y may be greater than or equal to the second length L2 of the vertical straight portion AS2 measured along the direction Y.

In FIG. 16B, the dummy gate structures 160 (referring to FIG. 16A) are replaced with high-k/metal gate structures 220. The high-k/metal gate structures 220 may inherit the shape of the dummy gate structures 160 (referring to FIG. 15A). For example, the gate structure 220 have the first profiles 220A overlapping the nanosheet subsets NS. As aforementioned, the first profile 220A has a width WA1′ adjacent to the dielectric wall 142 and a width WA2′ adjacent to the STI structures 152, and the width WA1′ is greater than the width WA2′. In addition, the second profile 220B over the dielectric wall 142 may have a width WB′ greater than a width WC′ of the third profile 220C over the STI structure. In the present embodiments, each of the sidewalls AS' of the first profiles 220A of the gate structure 220 has a slope portion AS1′ adjacent to the dielectric wall 142 and a vertical straight portion AS2′ away from the dielectric wall 142. In some examples, a first length L1′ of the slope portion AS1′ measured along the direction Y is less than a second length L2′ of the vertical straight portion AS2′ measured along the direction Y. In some other examples, the first length L1′ of the slope portion AS1′ measured along the direction Y is greater than or equal to the second length L2′ of the vertical straight portion AS2′ measured along the direction Y. Other details of the present embodiments are similar to those illustrated above, and therefore not repeated herein.

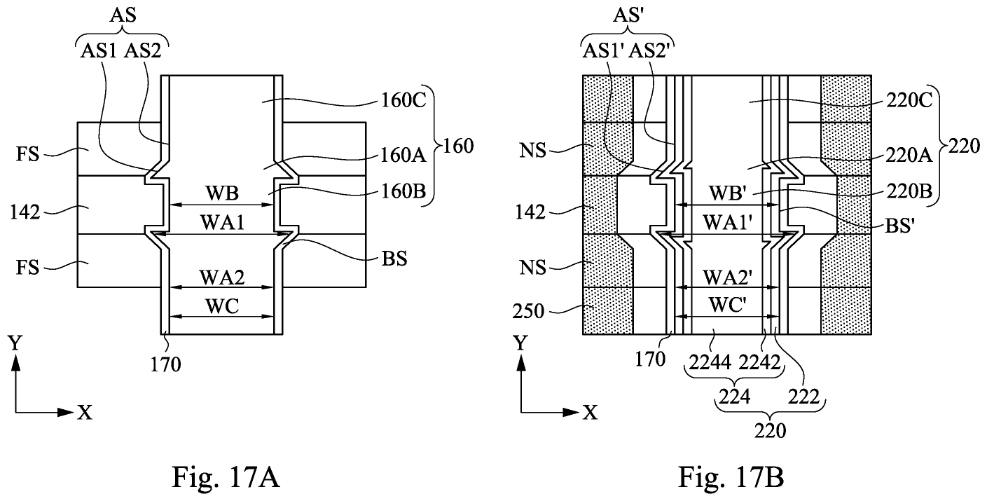

FIGS. 17A and 17B illustrate top views of intermediate stages in the manufacture of a semiconductor device in accordance with some embodiments of the present disclosure. Details of the present embodiments are similar to those illustrated in the embodiments of FIGS. 16A and 16B, except that the width WB of the second profile 160B of the gate structures 160 is substantially equal to the width WC of the third profile 160C of the gate structures 160, as shown in FIG. 17A. In the present embodiments, the width WA1 of the first profile 160A may be greater than the width WB of the second profile 160B, and the width WA2 of the first profile 160A may be substantially equal to the width WC of the third profile 160C. Referring to FIG. 17B, the dummy gate structures 160 (referring to FIG. 17A) are replaced with high-k/metal gate structures 220. The high-k/metal gate structures 220 may inherit the shape of the dummy gate structures 160 (referring to FIG. 17A). For example, the width WB′ of the second profile 220B of the gate structures 220 is substantially equal to the width WC′ of the third profile 220C of the gate structures 220, the width WA1′ of the first profile 220A may be greater than the width WB′ of the second profile 220B, and the width WA2′ of the first profile 220A may be substantially equal to the width WC′ of the third profile 220C, as shown in FIG. 17B. Other details of the present embodiments are similar to those illustrated in the embodiments of FIGS. 16A and 16B, and thereto not repeated herein.

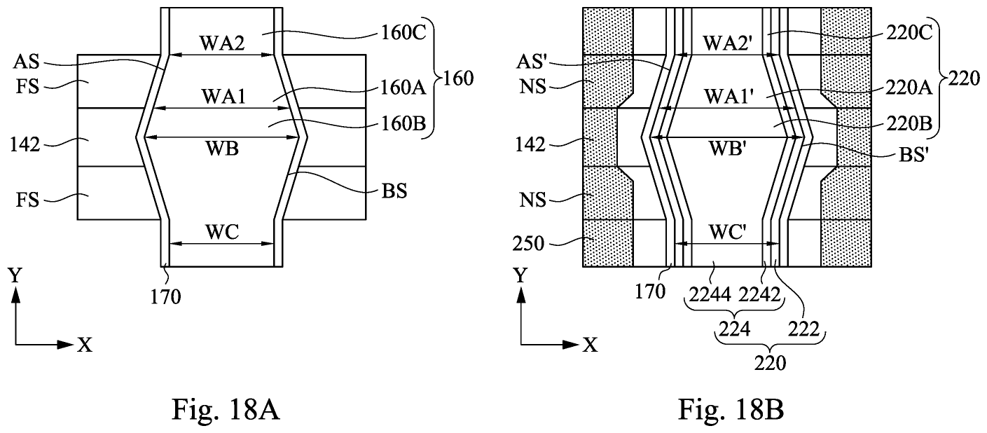

FIGS. 18A and 18B illustrate top views of intermediate stages in the manufacture of a semiconductor device in accordance with some embodiments of the present disclosure. Details of the present embodiments are similar to those illustrated above, except that the first profiles 160A and the second profiles 160B of the dummy gate structure 160 may form a hexagon.

Referring to FIG. 18A, each of the sidewall AS of the first profiles 160A of the gate structure 160 and a neighboring portion of the sidewall BS of the second profiles 160B of the gate structure 160 form a slope sidewall, and two slope sidewalls meets over the dielectric wall 142. Through the design, the width WA1 of the first profile 160A adjacent to the dielectric wall 142 is greater than the width WA2 of the first profile 160A adjacent to the STI structures 152. In the embodiments, the width WB of the second profile 160B is greater than the width WA1 and WA2 of the first profile 160A and the width WC of the third profile 160C. Through the configuration, the gate structure 160 has a larger CD at wall side and a less CD away from the wall side. When a channel release process may cause the sheets have thicker portions at wall side and thinner portions away from the wall side, by covering the thicker portions of the sheets at wall-side with the gate structure 160 with larger CD, the device can be boosted by better SCE.

In FIG. 18B, the dummy gate structures 160 (referring to FIG. 18A) are replaced with high-k/metal gate structures 220. The high-k/metal gate structures 220 may inherit the shape of the dummy gate structures 160 (referring to FIG. 18A). For example, the gate structure 220 have the first profiles 220A overlapping the nanosheet subsets NS. As aforementioned, the first profile 220A has a width WA1′ adjacent to the dielectric wall 142 and a width WA2′ adjacent to the STI structures 152, and the width WA1′ is greater than the width WA2′. In the present embodiments, each of the sidewalls AS' of the first profiles 220A of the gate structure 220 and a neighboring portion of the sidewall BS of the second profiles 220B of the gate structure 220 form a slope sidewall, and two slope sidewalls meets overlap the dielectric wall 142. In the embodiments, the width WB′ of the second profile 220B is greater than the width WA1′ and WA2′ of the first profile 220A and the width WC′ of the third profile 220C. Other details of the present embodiments are similar to those illustrated above, and therefore not repeated herein.

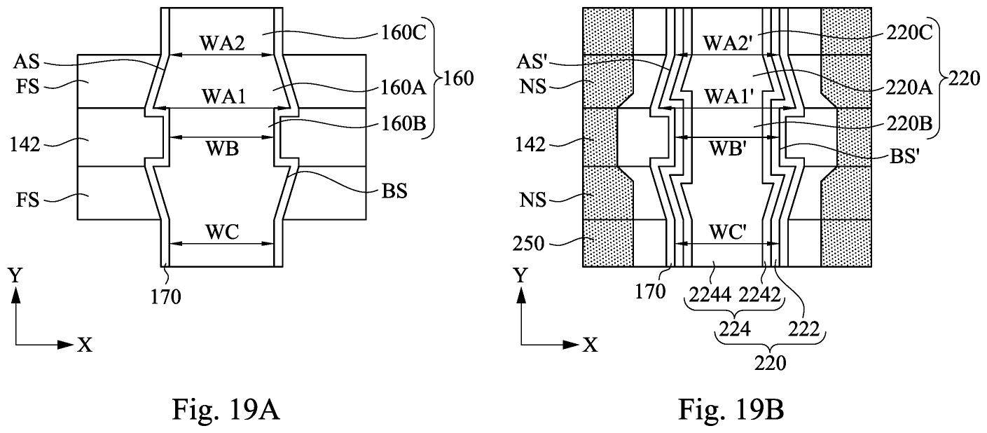

FIGS. 19A and 19B illustrate top views of intermediate stages in the manufacture of a semiconductor device in accordance with some embodiments of the present disclosure. Details of the present embodiments are similar to those illustrated in the embodiments of FIGS. 18A and 18B, except that the width WB of the second profile 160B of the gate structures 160 is substantially equal to the width WC of the third profile 160C of the gate structures 160, as shown in FIG. 19A. In the present embodiments, the width WA1 of the first profile 160A may be greater than the width WB of the second profile 160B, and the width WA2 of the first profile 160A may be substantially equal to the width WC of the third profile 160C. Referring to FIG. 19B, the dummy gate structures 160 (referring to FIG. 19A) are replaced with high-k/metal gate structures 220. The high-k/metal gate structures 220 may inherit the shape of the dummy gate structures 160 (referring to FIG. 19A). For example, the width WB′ of the second profile 220B of the gate structures 220 is substantially equal to the width WC′ of the third profile 220C of the gate structures 220, the width WA1′ of the first profile 220A may be greater than the width WB′ of the second profile 220B, and the width WA2′ of the first profile 220A may be substantially equal to the width WC′ of the third profile 220C, as shown in FIG. 19B. Other details of the present embodiments are similar to those illustrated in the embodiments of FIGS. 18A and 18B, and thereto not repeated herein.

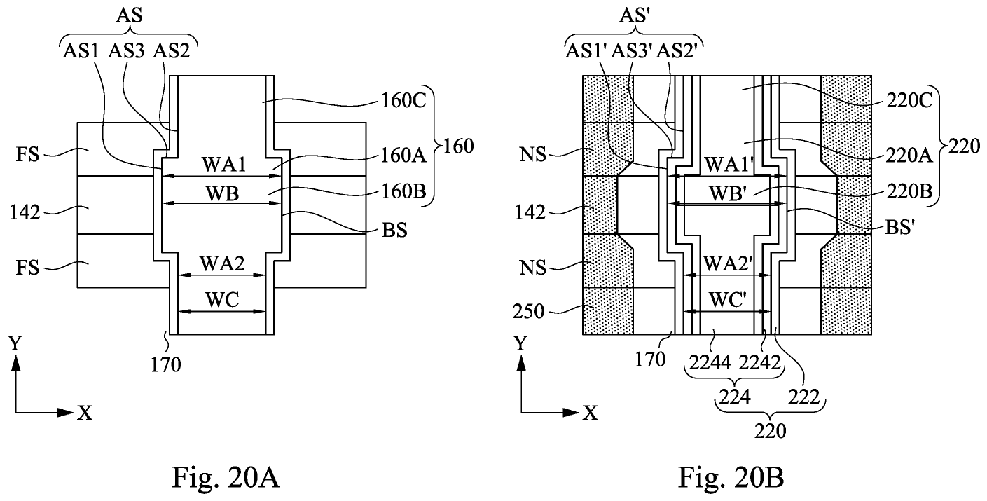

FIGS. 20A and 20B illustrate top views of intermediate stages in the manufacture of a semiconductor device in accordance with some embodiments of the present disclosure. Details of the present embodiments are similar to those illustrated above, except a portion of the first profile 160A of the gate structure 160 and the second profile 160B of the gate structure 160 form a rectangle.

Referring to FIG. 20A, the first profile 160A of the gate structure 160 over the nanosheet subsets NS has a step sidewall AS connected between the sidewall BS of the second profile 160B of the gate structure 160 and the sidewall CS of the third profile 160C of the gate structure 160, as shown in FIG. 20A. The step sidewall AS include a first vertical portion AS1 neighboring the dielectric wall 142, a second vertical portion AS2 away from the dielectric wall 142, and a horizontal portion AS3 connecting the first vertical portion AS1 to the second vertical portion AS2. In the context, it is noted that a vertical portion may extend substantially along the direction Y in the top view, and a horizontal portion may extend substantially along the direction X in the top view. Through the design, the width WA1 of the first profile 160A adjacent to the dielectric wall 142 is greater than the width WA2 of the first profile 160A adjacent to the STI structures 152. Through the configuration, the gate structure 160 has a larger CD at wall side and a less CD away from the wall side. When a channel release process may cause the sheets have thicker portions at wall side and thinner portions away from the wall side, by covering the thicker portions of the sheets at wall-side with the gate structure 160 with larger CD, the device can be boosted by better SCE.

In FIG. 20B, the dummy gate structures 160 (referring to FIG. 20A) are replaced with high-k/metal gate structures 220. The high-k/metal gate structures 220 may inherit the shape of the dummy gate structures 160 (referring to FIG. 20A). For example, the gate structure 220 have the first profiles 220A overlapping the nanosheet subsets NS. As aforementioned, the first profile 220A has a width WA1′ adjacent to the dielectric wall 142 and a width WA2′ adjacent to the STI structures 152, and the width WA1′ is greater than the width WA2′. In the present embodiments, the first profile 220A of the gate structure 220 over the nanosheet subsets NS has a step sidewall AS' connected between the sidewall BS' of the second profile 220B of the gate structure 220 and the sidewall CS' of the third profile 220C of the gate structure 220, as shown in FIG. 20B. The step sidewall AS' include a first vertical portion AS1′ neighboring the dielectric wall 142, a second vertical portion AS2′ away from the dielectric wall 142, and a horizontal portion AS3′ connecting the first vertical portion AS1′ to the second vertical portion AS2′. Other details of the present embodiments are similar to those illustrated above, and therefore not repeated herein.

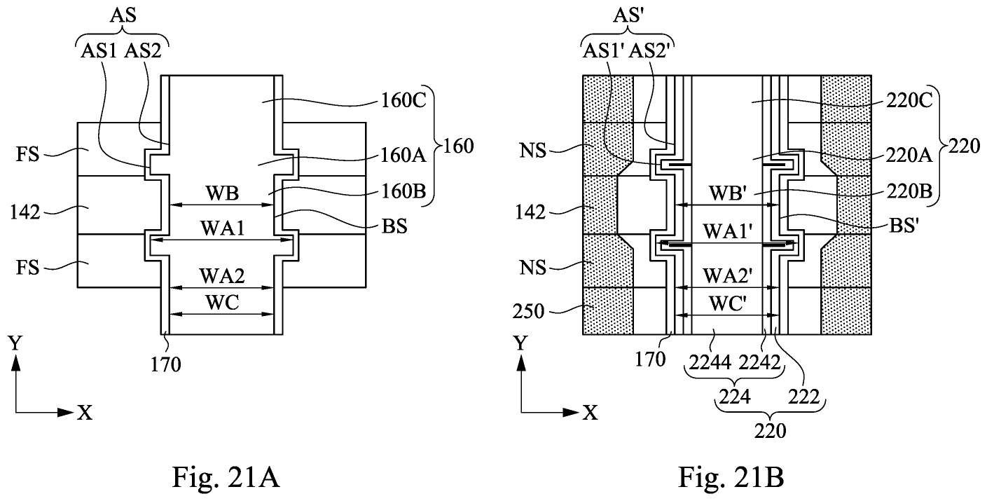

FIGS. 21A and 21B illustrate top views of intermediate stages in the manufacture of a semiconductor device in accordance with some embodiments of the present disclosure. Details of the present embodiments are similar to those illustrated in the embodiments of FIGS. 20A and 20B, except that the width WB of the second profile 160B of the gate structures 160 is substantially equal to the width WC of the third profile 160C of the gate structures 160, as shown in FIG. 21A. In the present embodiments, the width WA1 of the first profile 160A may be greater than the width WB of the second profile 160B, and the width WA2 of the first profile 160A may be substantially equal to the width WC of the third profile 160C. Referring to FIG. 21B, the dummy gate structures 160 (referring to FIG. 21A) are replaced with high-k/metal gate structures 220. The high-k/metal gate structures 220 may inherit the shape of the dummy gate structures 160 (referring to FIG. 21A). For example, the width WB′ of the second profile 220B of the gate structures 220 is substantially equal to the width WC′ of the third profile 220C of the gate structures 220, the width WA1′ of the first profile 220A may be greater than the width WB′ of the second profile 220B, and the width WA2′ of the first profile 220A may be substantially equal to the width WC′ of the third profile 220C, as shown in FIG. 21B. Other details of the present embodiments are similar to those illustrated in the embodiments of FIGS. 20A and 20B, and thereto not repeated herein.

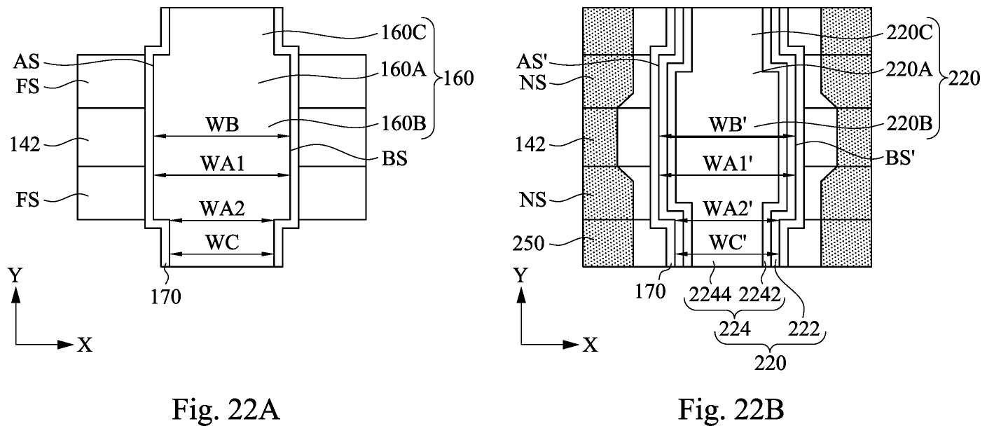

FIGS. 22A and 22B illustrate top views of intermediate stages in the manufacture of a semiconductor device in accordance with some embodiments of the present disclosure. Details of the present embodiments are similar to those illustrated above, except an entirety of the first profile 160A of the gate structure 160 and the second profile 160B of the gate structure 160 form a rectangle.

Referring to FIG. 22A, the sidewall AS of the first profile 160A and the sidewall BS of the second profile 160B form a vertical straight sidewall. Through the design, the width WA1 of the first profile 160A adjacent to the dielectric wall 142 is substantially equal to the width WA2 of the first profile 160A adjacent to the STI structures 152. In the embodiments, the width WB of the second profile 160B is substantially equal to the width WA1 and WA2 of the first profile 160A, and the width WC of the third profile 160C is less than the width WA1 and WA2 of the first profile 160A.

In FIG. 22B, the dummy gate structures 160 (referring to FIG. 22A) are replaced with high-k/metal gate structures 220. The high-k/metal gate structures 220 may inherit the shape of the dummy gate structures 160 (referring to FIG. 21A). For example, the sidewall AS' of the first profile 220A and the sidewall BS' of the second profile 220B form a vertical straight sidewall. The width WA1′ of the first profile 220A adjacent to the dielectric wall 142 is substantially equal to the width WA2′ of the first profile 220A adjacent to the STI structures 152. In the embodiments, the width WB′ of the second portion “0B is substantially equal to the width WA1′ and WA2′ of the first portion “0A, and the width WC′ of the third profile 220C is less than the width WA1′ and WA2′ of the first profile 220A. Other details of the present embodiments are similar to those illustrated above, and therefore not repeated herein.

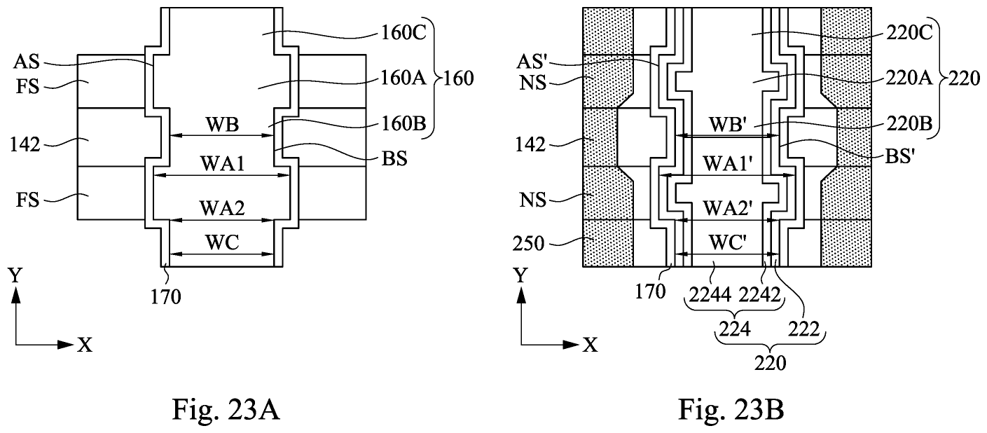

FIGS. 23A and 23B illustrate top views of intermediate stages in the manufacture of a semiconductor device in accordance with some embodiments of the present disclosure. Details of the present embodiments are similar to those illustrated in the embodiments of FIGS. 22A and 22B, except that the width WB of the second profile 160B of the gate structures 160 is substantially equal to the width WC of the third profile 160C of the gate structures 160, as shown in FIG. 23A. In the present embodiments, the width WA1 of the first profile 160A may be greater than the width WB of the second profile 160B, and the width WA2 of the first profile 160A may be greater than the width WC of the third profile 160C. Referring to FIG. 23B, the dummy gate structures 160 (referring to FIG. 23A) are replaced with high-k/metal gate structures 220. The high-k/metal gate structures 220 may inherit the shape of the dummy gate structures 160 (referring to FIG. 23A). For example, the width WB′ of the second profile 220B of the gate structures 220 is substantially equal to the width WC′ of the third profile 220C of the gate structures 220, the width WA1′ of the first profile 220A may be greater than the width WB′ of the second profile 220B, and the width WA2′ of the first profile 220A may be greater than the width WC′ of the third profile 220C, as shown in FIG. 23B. Other details of the present embodiments are similar to those illustrated in the embodiments of FIGS. 22A and 22B, and thereto not repeated herein.

In various embodiments, from the top views (referring to FIGS. 15A-15B), the gate structure 160/220 may have a curved sidewall profile between the first sides of the one or more semiconductor channels and the second sides of the one or more semiconductor channels.

In various embodiments, from the top views (referring to FIGS. 16A-19B), the gate structure 160/220 may have a tapered sidewall profile between the first sides of the one or more semiconductor channels and the second sides of the one or more semiconductor channels.

In various embodiments, from the top views (referring to FIGS. 20A-21B), the gate structure 160/220 may have a stepped sidewall profile between the first sides of the one or more semiconductor channels and the second sides of the one or more semiconductor channels.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that gate critical dimension (CD) abut forksheet wall is enlarged by using an optical proximity correction (OPC) rule, such that the gate structure with larger CD can cover the thicker portions of the sheets at wall-side resulting in worse I_{off}, thereby boosting the device by better short channel effect (SCE). Another advantage is that the forksheet tri-gate scheme brings in higher I_{off} near wall side, thereby mitigating SCE. Still another advantage is that the process is simple and can be performed without extra cost. Still another advantage is that the source/drain contacts may be arranged according to the configuration of gate, thereby keeping isolating from each other by low-k dielectrics.

According to some embodiments of the present disclosure, a semiconductor device includes a dielectric wall, an isolation structure, one or more first semiconductor channels, one or more second semiconductor channels, and a gate structure. The dielectric wall is on a substrate and extending along a first direction from a top view. The isolation structure is in the substrate and having a top surface lower than a top surface of the dielectric wall. The one or more first semiconductor channels are on a first side of the dielectric wall. The one or more second semiconductor channels are on a second side of the dielectric wall opposite the first side of the dielectric wall. The gate structure extends across the one or more first semiconductor channels and the one or more second semiconductor channels along a second direction different from the first direction from the top view. From the top view the gate structure comprises a first profile over the one or more first semiconductor channels and a second profile over the isolation structure, the first profile has a first width at the first side of the dielectric wall, and the first width is greater than a width of the second profile.

According to some embodiments of the present disclosure, a semiconductor device includes a dielectric wall, one or more semiconductor channels, and a gate structure. The dielectric wall is on a substrate. The one or more semiconductor channels laterally extends from a side surface of the dielectric wall, each of the one or more semiconductor channels having a first side interfacing the dielectric wall and a second side facing away from the dielectric wall. The gate structure is over the one or more semiconductor channels. From a top view the gate structure has a first width adjacent to the first sides of the one or more semiconductor channels and a second width adjacent to the second sides of the one or more semiconductor channels, and the first width of the gate structure is greater than the second width of the gate structure.

According to some embodiments of the present disclosure, a method includes forming an epitaxial stack over a substrate, the epitaxial stack comprising alternating first semiconductor layers and second semiconductor layers; forming a dielectric wall in the epitaxial stack; removing the first semiconductor layers, while leaving a first subset of the second semiconductor layers on a first side of the dielectric wall and a second subset of the semiconductor layers on the second side of the dielectric wall; and forming a gate structure over the first and second subsets of the second semiconductor layers, wherein from a top view the gate structure has a first width at the first side of the dielectric wall and a second width at a position offset from the dielectric wall, and the first width is greater than the second width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a dielectric wall on a substrate and extending along a first direction from a top view;
an isolation structure in the substrate and having a top surface lower than a top surface of the dielectric wall;
one or more first semiconductor channels on a first side of the dielectric wall;
one or more second semiconductor channels on a second side of the dielectric wall opposite the first side of the dielectric wall; and
a gate structure extending across the one or more first semiconductor channels and the one or more second semiconductor channels along a second direction different from the first direction from the top view,
wherein from the top view the gate structure comprises a first profile over the one or more first semiconductor channels and a second profile over the isolation structure, the first profile has a first width at the first side of the dielectric wall, and the first width is greater than a width of the second profile.

2. The semiconductor device of claim 1, wherein from the top view the first profile has a second width at a position offset from the first side of the dielectric wall, and the second width is less than the first width.

3. The semiconductor device of claim 2, wherein the second width of the first profile of the gate structure is substantially equal to the width of the second profile of the gate structure.

4. The semiconductor device of claim 1, wherein from the top view the gate structure further comprises a third profile over the dielectric wall, and the third profile has a width greater than the width of the second profile.

5. The semiconductor device of claim 1, wherein from the top view the gate structure further comprises a third profile over the dielectric wall, and the third profile has a width substantially equal to the first width of the first profile.

6. The semiconductor device of claim 1, wherein from the top view the gate structure further comprises a third profile over the dielectric wall, and the third profile has a width less than the first width of the first profile.

7. The semiconductor device of claim 1, wherein from the top view the gate structure further comprises a third profile over the one or more second semiconductor channels, the third profile has a width at the second side of the dielectric wall and greater than the width of the second profile.

8. The semiconductor device of claim 7, wherein the third profile of the gate structure is formed from a different metal composition than the first profile of the gate structure.

9. A semiconductor device, comprising:
a dielectric wall on a substrate;
one or more semiconductor channels laterally extending from a side surface of the dielectric wall, each of the one or more semiconductor channels having a first side interfacing the dielectric wall and a second side facing away from the dielectric wall; and
a gate structure over the one or more semiconductor channels, wherein from a top view the gate structure has a first width adjacent to the first sides of the one or more semiconductor channels and a second width adjacent to the second sides of the one or more semiconductor channels, and the first width of the gate structure is greater than the second width of the gate structure.

10. The semiconductor device of claim 9, wherein each of the one or more semiconductor channels is thicker at the first side than at the second side.

11. The semiconductor device of claim 9, further comprising:
a source/drain epitaxial structure connecting the one or more semiconductor channels; and
a source/drain contact over the source/drain epitaxial structure, wherein from the top view the source/drain contact has a first width adjacent to the first sides of the one or more semiconductor channels and a second width adjacent to the second sides of the one or more semiconductor channels, and the first width of the source/drain contact is less than the second width of the source/drain contact.

12. The semiconductor device of claim 9, wherein from the top view the gate structure has a curved sidewall profile between the first sides of the one or more semiconductor channels and the second sides of the one or more semiconductor channels.

13. The semiconductor device of claim 9, wherein from the top view the gate structure has a stepped sidewall profile between the first sides of the one or more semiconductor channels and the second sides of the one or more semiconductor channels.

14. The semiconductor device of claim 9, wherein from the top view the gate structure has a tapered sidewall profile between the first sides of the one or more semiconductor channels and the second sides of the one or more semiconductor channels.

15. The semiconductor device of claim 14, further comprising:
a source/drain epitaxial structure interfacing the one or more semiconductor channels; and
a source/drain contact over the source/drain epitaxial structure, wherein from the top view the source/drain contact has a non-linear sidewall.

16. The semiconductor device of claim 15, wherein from the top view the non-linear sidewall of the source/drain contact has a recessed profile over the dielectric wall.

17. The semiconductor device of claim 16, wherein from the top view the recessed profile of the source/drain contact is also over the one or more semiconductor channels.

18. A method, comprising:
forming an epitaxial stack over a substrate, the epitaxial stack comprising alternating first semiconductor layers and second semiconductor layers;
forming a dielectric wall in the epitaxial stack;
removing the first semiconductor layers, while leaving a first subset of the second semiconductor layers on a first side of the dielectric wall and a second subset of the semiconductor layers on a second side of the dielectric wall; and
forming a gate structure over the first and second subsets of the second semiconductor layers, wherein from a top view the gate structure has a first width at the first side of the dielectric wall and a second width at a position offset from the dielectric wall, and the first width is greater than the second width.

19. The method of claim 18, wherein from the top view the gate structure has a third width at the second side of the dielectric wall, and the third width is greater than the second width.

20. The method of claim 18, further comprising:
forming an n-type source/drain region interfacing the first subset of the second semiconductor layers;
forming a p-type source/drain region interfacing the second subset of the second semiconductor layers; and
forming a source/drain contact extending across the dielectric wall, the n-type source/drain region and the p-type source/drain region, wherein from the top view the source/drain contact has a recessed profile over the dielectric wall.
